(19) United States
(12) Patent Application Publication
(10) Pub. No.: US 2025/0387973 A1
(43) Pub. Date: Dec. 25, 2025

(54) APPARATUS AND METHOD FOR PROGRAMMED MULTIMATERIAL ASSEMBLY BY SYNERGIZED 3D PRINTING AND FREEFORM LASER INDUCTION

(71) Applicant: The Curators of the University of Missouri, Columbia, MO (US)

(72) Inventors: Jian LIN, Columbia, MO (US); Bujingda ZHENG, Columbia, MO (US)

(21) Appl. No.: 19/243,935

(22) Filed: Jun. 20, 2025

Related U.S. Application Data
(60) Provisional application No. 63/662,647, filed on Jun. 21, 2024.

(51) Int. Cl. B29C 64/336; B29C 64/118; B29C 64/268; B29C 64/393; B29L 31/34; B33Y 10/00; B33Y 30/00; B33Y 50/02

(52) U.S. Cl. CPC B29C 64/336; B29C 64/118; B29C 64/268; B29C 64/393; B29L 2031/3406; B33Y 10/00; B33Y 30/00; B33Y 50/02

(57) ABSTRACT

A system and method for programmed multimaterial assembly via a freeform multimaterial assembly process, including controlling a multi-axis actuation system to synergistically integrate a fused filament fabrication (FFF) process and a direct ink writing (DIW) process with a freeform laser induction (FLI) process for the construction of 3D engineered structures; causing generation, via the controlled multi-axis actuation system, of structural components of one or more target 3D engineered structures via the FFF process and the DIW process; causing generation, via the controlled multi-axis actuation system and based on the generated structural components, of functional materials via the FLI process; and causing construction, via the controlled multi-axis actuation system, and based on the generated structural components and the generated functional materials, of the one or more target 3D engineered structures.

### CROSS-REFERENCE TO RELATED APPLICATIONS

This application claims the benefit of priority to U.S. Provisional Application No. 63/662,647, filed Jun. 21, 2024, titled “APPARATUS AND METHOD FOR PROGRAMMED MULTIMATERIAL ASSEMBLY BY SYNERGIZED 3D PRINTING AND FREEFORM LASER INDUCTION,” the contents and disclosures of which are hereby incorporated herein by reference in their entirety.

### STATEMENT REGARDING FEDERALLY SPONSORED RESEARCH OR DEVELOPMENT

This invention was made with government support under W912HZ-21-2-0050 awarded by the United States Army Corps of Engineers/Engineering Research and Development Center, and 1933861 and 1825352 awarded by the National Science Foundation. The government has certain rights in the invention.

### BACKGROUND OF THE DISCLOSURE

The field of the disclosure relates generally to engineered structures and the application and implementations thereof, and more specifically to manufacturing processes capable of producing three-dimensional (3D) engineered structures.

In nature, structural and functional materials often form programmed 3D assemblies to perform functions, inspiring researchers to explore new design principles and fabrication methodologies for creating engineered multifunctional 3D structures. Despite much progress, a general method to fabricate and assemble a broad range of materials into functional 3D objects remains limited. Traditionally, hybridized fabrication techniques can be used to achieve a stated (e.g., fabrication) goal, but they require multiple, subsequent processes. For instance, producing multilayer 3D printed circuit boards (PCBs) entails steps of etching, lamination, heated pressing, drilling, etc. The processes require high capital investment while generating unwanted waste streams, thus posing a significant challenge to sustainability. To enhance material utilization efficiency and circumvent the challenge of assembling multimaterials, several new technologies such as mechanics-driven assembly, transfer printing, and multimaterial 3D printing have emerged.

What is needed is a multimaterial assembly framework capable of leveraging and synergizing a plurality of manufacturing techniques to enable the fabrication of integrated devices with structural integrity, customized material properties, and functional enhancements. Such a framework would represent an integrated approach useful for applications in electronics, robotics, microfluidics, and beyond.

### SUMMARY

In one aspect, a fabrication system for programmed multimaterial assembly via a freeform multimaterial assembly process (FMAP). The fabrication system includes a multi-axis actuation system and a computing device including at least one processor and at least one memory in communication with the at least one processor, the computing device being in operative communication with the multi-axis actuation system, and the at least one memory storing instructions that, when executed, cause the at least one processor to: control the multi-axis actuation system to synergistically integrate a fused filament fabrication (FFF) process and a direct ink writing (DIW) process with a freeform laser induction (FLI) process for the construction of 3D engineered structures; cause generation, via the controlled multi-axis actuation system, of structural components of one or more target 3D engineered structures via the FFF process and the DIW process; cause generation, via the controlled multi-axis actuation system and based on the generated structural components, of functional materials via the FLI process; and cause construction, via the controlled multi-axis actuation system, and based on the generated structural components and the generated functional materials, of the one or more target 3D engineered structures.

In another aspect, a computer-implemented method for programmed multimaterial assembly via a freeform multimaterial assembly process, implemented via a multi-axis actuation system in operative communication with a computing device, the computing device including at least one processor and at least one memory in communication with the at least one processor. The computer-implemented method includes: controlling the multi-axis actuation system to synergistically integrate a fused filament fabrication (FFF) process and a direct ink writing (DIW) process with a freeform laser induction (FLI) process for the construction of 3D engineered structures; causing generation, via the controlled multi-axis actuation system, of structural components of one or more target 3D engineered structures via the FFF process and the DIW process; causing generation, via the controlled multi-axis actuation system and based on the generated structural components, of functional materials via the FLI process; and causing construction, via the controlled multi-axis actuation system, and based on the generated structural components and the generated functional materials, of the one or more target 3D engineered structures.

### DESCRIPTION OF THE DRAWINGS

The patent or application file contains at least one drawing executed in color. Copies of this patent or patent application publication with color drawing(s) will be provided by the Office upon request and payment of the necessary fee.

The accompanying drawings, which are incorporated in and form a part of the specification, illustrate the embodiments of the present disclosure and together with the description, serve to explain the principles of the disclosure. Those of skill in the art will understand that the drawings, described below, are for illustrative purposes only. The drawings are not intended to limit the scope of the present disclosure in any way.

FIG. 1A illustrates a schematic showing an FMAP platform according to one embodiment of the present disclosure.

FIG. 1B illustrates a schematic of end effectors for FFF, DIW, and FLI according to one embodiment of the present disclosure.

FIG. 1C illustrates a workflow of fabricating a device by FMAP according to one embodiment of the present disclosure.

FIG. 1D illustrates a configuration scheme of a fabricated device according to one embodiment of the present disclosure.

FIG. 1E illustrates photographs of a fabricated device according to one embodiment of the present disclosure.

FIG. 2A illustrates scanning electron microscopy (SEM) and other images of metals and metal oxides in lignin (LIG) induced from various polymers according to one embodiment of the present disclosure.

FIG. 2B illustrates cross-sectional SEM images collected from regions of LIG embedded 3D structures according to one embodiment of the present disclosure.

FIG. 2C illustrates a photograph of a LIG/Ag electrode to light up an LED according to one embodiment of the present disclosure.

FIG. 3A illustrates plots of properties of LIG and LIG/Ag composite in polycarbonate (PC) according to one embodiment of the present disclosure.

FIG. 3B illustrates different 3D structures printed from PC with encased LIG inside according to one embodiment of the present disclosure.

FIG. 4A illustrates diagrams corresponding to a crossbar circuit according to one embodiment of the present disclosure

FIG. 4B illustrates a diagram, a plot, and photographs in connection with a human machine interface (HMI) embodiment of the present disclosure.

FIG. 4C illustrates a slider embodiment according to one embodiment of the present disclosure

FIG. 5A illustrates a diagram of a schematic of an integrated UV sensor with electrical components and photographs of an as-fabricated device and the device under UV light according to one embodiment of the present disclosure.

FIG. 5B illustrates a diagram/photograph illustrating a schematic and a photograph of a spring with a PC shell and a LIG core according to one embodiment of the present disclosure.

FIG. 5C illustrates a diagram/photograph illustrating a micro electromagnet according to one embodiment of the present disclosure.

FIG. 6A illustrates a diagram of a schematic of an assembled microfluidic flow reactor for zeolitic imidazolate framework (ZIF) synthesis according to one embodiment of the present disclosure.

FIG. 6B is a photograph of a fabricated reactor according to one embodiment of the present disclosure.

FIG. 6C is a diagram illustrating thermal images of the reactor shown in FIG. 6B taken at different flow rates when power is on according to one embodiment of the present disclosure.

FIG. 6D is a diagram illustrating finite element analysis (FEA) simulation on the temperature distribution of channels at different flow rates according to one embodiment of the present disclosure.

FIG. 6E is a collection of photographs of samples synthesized at various temperatures according to one embodiment of the present disclosure.

FIG. 6F is a plot of UV-Vis spectra of samples according to one embodiment of the present disclosure.

FIG. 6G is an image of synthesized ZIF-8 according to one embodiment of the present disclosure.

FIG. 6H is plot illustrating an XRD spectrum of synthesized ZIF-8 according to one embodiment of the present disclosure.

FIG. 7A illustrates diagram for design and modeling of electrodes for a wireless LED according to one embodiment of the present disclosure.

FIG. 7B illustrates diagram for toolpaths for FFF, FLI, and DIW according to one embodiment of the present disclosure.

FIG. 7C illustrates time-lapse images of different fabrication steps for a wireless LED according to one embodiment of the present disclosure.

FIG. 8 illustrates a diagram of a workflow of using FMAP to fabricate a 3D wireless LED with LIG/Ag electrodes according to one embodiment of the present disclosure.

FIG. 9A illustrates cross-sectional optical images of an LIG induced from PC according to one embodiment of the present disclosure.

FIG. 9B illustrates a plot showing a change of the resistance of LIG in the z-axis direction vs. the layer height according to one embodiment of the present disclosure.

FIG. 10 illustrates a plot showing sheet resistance of LIG as a function of laser scan rate according to one embodiment of the present disclosure.

FIG. 11A illustrates photographs showing cross sections of LIG samples made by different laser powers according to one embodiment of the present disclosure.

FIG. 11B illustrates a plot showing LIG thickness as a function of laser power according to one embodiment of the present disclosure.

FIG. 12A illustrates a photograph showing a LIG strip according to one embodiment of the present disclosure.

FIG. 12B illustrates a photograph showing a LIG strip according to another embodiment of the present disclosure.

FIG. 12C illustrates a photograph showing a LIG and Ag strip according to one embodiment of the present disclosure.

FIG. 12D illustrates a photograph showing laser induced Ag on PC according to one embodiment of the present disclosure.

FIG. 13A illustrates a diagram showing a schematic that illustrates the structure of a tensile testing specimen with LIG embedded inside according to one embodiment of the present disclosure.

FIG. 13B illustrates a plot showing stress-strain curves of PC specimens with varied thickness LIG according to one embodiment of the present disclosure.

FIG. 13C illustrates a plot showing stress-strain curves of PC specimens with varied width LIG according to one embodiment of the present disclosure.

FIG. 14 illustrates a plot showing Raman spectra of LIG from PC induced with different laser powers according to one embodiment of the present disclosure.

FIG. 15A illustrates an “MU” logo made from LIG embedded in a printed polyvinylidene fluoride structure according to one embodiment of the present disclosure.

FIG. 15B illustrates an airfoil embedded with a LIG Zigzag pattern in PC according to one embodiment of the present disclosure.

FIG. 15C illustrates an LIG lattice structure embedded in a PC cuboid according to one embodiment of the present disclosure.

FIG. 15D illustrates a printed PC gear embedded with LIG according to one embodiment of the present disclosure.

FIG. 15E illustrates a schwarz diamond surface in PC according to one embodiment of the present disclosure.

FIG. 15F illustrates a 3D LIG fan embedded in PC according to one embodiment of the present disclosure.

FIG. 16A illustrates a diagram showing a workflow of fabricating the 3D “MU” logo according to one embodiment of the present disclosure.

FIG. 16B illustrates a diagram/photograph showing a scheme and a photograph showing the structure of a fabricated 3D “MU” logo according to one embodiment of the present disclosure.

FIG. 17A illustrates photographs showing fabrication steps for a crossbar LED array by FMAP according to one embodiment of the present disclosure.

FIG. 17B illustrates photographs showing fabrication steps for another embodiment of a crossbar LED array by FMAP according to one embodiment of the present disclosure.

FIG. 18A illustrates a plot showing capacitance changes as a function of length of electrodes according to one embodiment of the present disclosure.

FIG. 18B illustrates a plot showing capacitance changes as a function thickness of an insulator in between two electrodes according to one embodiment of the present disclosure.

FIG. 19 illustrates a diagram showing a schematic showing the circuits and electrical components for a UV sensor according to one embodiment of the present disclosure.

FIG. 20 illustrates a plot showing I-V curves of a UV sensor at varying UV light intensities ranging according to one embodiment of the present disclosure.

FIG. 21 illustrates a diagram showing Von Mises stress distribution of a spring according to one embodiment of the present disclosure.

FIG. 22A illustrates a diagram/photograph showing a schematic showing an assembled manipulator and a photograph showing a strain sensor embedded gripper fabricated by FMAP according to one embodiment of the present disclosure.

FIG. 22B illustrates a plot showing resistance change as a function of load according to one embodiment of the present disclosure.

FIG. 22C illustrates a diagram showing a scheme showing a workflow of a feedback loop control according to one embodiment of the present disclosure.

FIG. 22D illustrates photographs showing the manipulator manipulating various objects according to one embodiment of the present disclosure.

FIG. 23 illustrates a plot of voltage response of a Hall sensor as an approached micro electromagnet is switched “on” and “off” according to one embodiment of the present disclosure.

FIG. 24 is a flow diagram of an example method according to one embodiment of the disclosure.

FIG. 25 is a block diagram schematically illustrating an example system in accordance with one embodiment of the disclosure.

FIG. 26 illustrates an example configuration of a remote or user computing device according to one embodiment of the disclosure.

FIG. 27 illustrates an example configuration of a database/server system according to one embodiment of the disclosure.

There are shown in the drawings arrangements that are presently discussed, it being understood, however, that the present embodiments are not limited to the precise arrangements and are instrumentalities shown. While multiple embodiments are disclosed, still other embodiments of the present disclosure will become apparent to those skilled in the art from the following detailed description, which shows and describes illustrative aspects of the disclosure. As will be realized, the invention is capable of modifications in various aspects, all without departing from the spirit and scope of the present disclosure. Accordingly, the drawings and detailed description are to be regarded as illustrative in nature and not restrictive.

### DETAILED DESCRIPTION

This disclosure presents an innovative manufacturing process that allows the seamless integration of both structural and functional materials into complex 3D engineered objects at scales such as a micrometer scale. This groundbreaking approach leverages the strengths of three techniques: freeform laser induction (FLI), direct ink writing (DIW), and fused filament fabrication (FFF). The FLI technique may include or be included within a freeform direct laser writing (FDLW) technique/process, and the FFF technique may include or be included within a fused deposition modeling technique/process. By established software control, these techniques can be implemented to work in synergy to realize the target 3D engineered structures with multifunctionality in a single apparatus.

FLI uses laser energy for targeted material transformation, ideal for integrating functional materials (e.g., conductive and/or semiconductive materials, such as in the form of electronic circuits or sensors) directly onto 3D surfaces. More specifically, FLI uses a focused laser beam to induce local changes in materials. In practice, the laser's energy is used to either heat, sinter, or chemically transform a precursor material into a functional component directly onto a three-dimensional surface. This ability to “write” functional features (such as conductive traces or sensor elements) right in place means that FLI can add electronic or responsive materials onto preformed structures.

DIW extrudes a variety of inks or pastes to create detailed, custom patterns and structures, especially useful when working with soft or composite materials. DIW is an extrusion-based additive manufacturing process that works much like drawing with a very precise, computer-guided “pen.” In this process, a viscous ink or paste—often containing polymers, nano/micro particles, or even conductive materials—is deposited through a fine nozzle along a predefined digital path. This layer-by-layer deposition allows for high customization and accommodates a wide range of materials; it is especially valued in research and development for fabricating soft electronics, hydrogels, and other composites with intricate internal geometries.

FFF is a form of 3D printing and melts and extrudes thermoplastic filaments to build robust structural parts layer by layer, and may be implemented for creating 3D printed objects. In FFF, a thermoplastic filament (such as PLA, ABS, or PETG) is continuously fed from a spool into a heated extrusion head, where it is melted then deposited layer by layer to build a three-dimensional object. This method is valued for its simplicity, cost-effectiveness, and robustness, making it the go-to choice for hobbyist-grade printers as well as for industrial prototyping. FFF primarily builds the structural component of a device, creating a durable scaffold that can sometimes be further functionalized with additional materials or processes.

Multimaterial 3D printing has potential benefits, including cost-effectiveness, reduced waste generation, and easy customization. For example, a direct ink writing (DIW) method enables to fabricate 3D soft electronics and light emitting diodes (LEDs). Embedded 3D printing facilitates production of flexible sensors by embedding functional carbon grease within a polymer encapsulation. A multi-nozzle DIW printer with a rapid material switching capability can print diverse wax-based structures. A core-shell DIW nozzle enables assembled multimaterials, such as epoxy/silicone, into different 3D structures, including a sandwiches and helices. Multi-axis fused filament fabrication (FFF) and conformal DIW can make conformal deposition of conductive filaments onto 3D curved surfaces.

However, within the realm of multimaterial fabrication, these techniques still face challenges of lacking versatility in precisely placing functional materials within 3D structures and access to broader material options. For instance, the embedded 3D printing necessitates preparation of a mold for the structural materials. This necessity imposes constraints on the capability of achieving complex geometries, such as in hollow and freestanding features. In the case of core-shell 3D printing, although it can print objects with inner structures made from functional materials, the functional and structural materials are extruded simultaneously and continuously, so depositing the functional materials in predesigned locations, such as outer surface, is not achievable. Besides the limitation in the complexity of printed structures, these techniques often suffer from limited materials options. For instance, the multi-nozzle DIW extrudes composite inks that contains both electrically conductive materials and polymers, rendering the resulting materials with low electrical conductivity and low mechanical strength. DLP is quite limited to photosensitive resins. Moreover, the process for multimaterial printing requires switching between different vats while purging non-polymerized residual materials out from the vats, which results in inefficient materials utilization. All these challenges supply a basis for the systems, methods, and/or techniques described herein that improve multimaterial fabrication methodologies with improved versatility in the structure complexity and broadened materials choices.

Described herein is a freeform multimaterial assembly process (FMAP) by integrating 3D printing (fused filament fabrication (FFF), direct ink writing (DIW)) with freeform laser induction (FLI). In one embodiment, 3D printing performs the 3D structural material assembly, while FLI fabricates the functional materials in predesigned 3D space by synergistic, programmed control. Example applications described herein and shown in the accompanying figures showcase the versatility of FMAP in spatially fabricating various types of functional materials (e.g., metals, semiconductors) within 3D structures for applications including but not limited to crossbar circuits for LED display, a strain sensor for multifunctional springs and haptic manipulators, a UV sensor, a 3D electromagnet as a magnetic encoder, capacitive sensors for human machine interface, and an integrated microfluidic reactor with a built-in Joule heater for nanomaterial synthesis. These examples underscore how FMAP redefines existing 3D printing and FLI for programmed multimaterial assembly. For example, in an integrated fabrication platform such as FMAP, FLI is paired with other 3D printing techniques to seamlessly embed features into complex architectures. Additionally, since DIW can handle materials that are not typically compatible with conventional extrusion methods, it opens innovative applications in microfabrication and flexible device production as described herein.

Further regarding challenges in this area, direct laser writing (DLW) has shown versatility in patterning various functional materials through induced photothermal or/and photochemical effects. This significantly expands the library of available materials ranging from laser-induced graphene (LIG), to metals, metal oxides, semiconductors, and ceramics. DLW can be used to assemble these functioning materials into 3D structures, even while this goal may be limited by its capability in fabricating the functional materials on 2D planes. Freeform laser induction (FLI) methods facilitated by a 5-axis laser processing platform enable direct fabrication of 3D conformable electronics on freeform surfaces. While this technique represents an advancement in DLW capabilities, spatially patterning functional materials within predesigned locations of 3D structures to create multifunctional objects remains a challenge.

As described herein, FFF is employed to construct structural components using available thermoplastic materials such as polylactic acid (PLA), polycarbonate (PC), polyethylene terephthalate glycol (PETG), thermoplastic polyurethane (TPU), polyvinylidene fluoride (PVDF), polyetheretherketone (PEEK), polyimide (PI), polyetherimide (PEI), and other extrudable materials. A multi-axis (e.g., 5-axis) FLI process selectively transforms printed material into laser-induced graphene (LIG) at predefined locations within the 3D space.

Depending on the intended application, DIW is used to deposit precursors for various functional materials, such as silver for improved conductivity, as well as materials like iron, cobalt, nickel, copper oxide, and zinc oxide, serving various purposes from electromagnets to UV sensing.

These materials are deposited onto LIG electrodes or FFF-manufactured stencils, and a second round of FLI is applied to trigger photothermal or photochemical effects, leading to the creation of composite materials, with or without an LIG matrix.

Such a versatile approach as described herein results in multifunctional objects with intricate 3D geometries. By combining the strengths of both FFF and FLI, functional materials can be either encapsulated within 3D printed objects or patterned onto their external surfaces, overcoming the limitation of previous methods. Unlike existing and/or conventional manufacturing methods solely utilizing FFF, DIW, or FLI, the processes described herein not only minimize waste and enable versatile material assembly in a freeform manner, but also multiply (e.g., triple) the available material selection. The approach described herein also streamlines the programmed assembly of both functional and structural materials into integrated 3D devices using a single apparatus, eliminating the need for post-processing steps typically associated with existing fabrication methods. Additionally, the present approach enhances the flexibility to process a wide range of functional materials without generating much waste, and maybe realized via a low setup cost and ease of use, making the approach accessible for a wide range of applications. The innovation techniques described herein mark a significant step forward in the realization of highly integrated, multifunctional 3D objects, with applications spanning, without limitation, from electronics, sensors, human-machine interfaces and robotics, to microfluidics.

To tackle the challenges and drawbacks of existing techniques, the approach described herein implements a freeform multimaterial assembly process (FMAP) that synergistically marries advantages of three techniques—FLI, DIW, and FFF—to seamlessly assemble both structural and laser-processable functional materials into 3D engineered objects with complex geometries and multifunctionalities. FFF can construct structural components from commercially available thermoplastics such as polycarbonate (PC), polyethylene terephthalate glycol (PETG) and thermoplastic polyurethane (TPU), and polyvinylidene fluoride (PVDF), while FLI selectively converts the FFF-printed material into LIG in predesigned position in the 3D space. DIW can deposit precursors onto LIG electrodes for later laser-inducing other functional materials, e.g., silver, iron, cobalt, nickel, and copper oxides, to obtain LIG-based functional composites. With the advantages of FFF and FLI, the functional materials are either encapsulated inside the printed 3D objects or on their outside surfaces, thus forming integrated functioning 3D devices. This includes, for example, and without limitation, a crossbar circuit for a light emitting diode (LED) array, strain sensors for an integrated multifunctional spring and a haptic manipulator, a UV sensor, a 3D electromagnet as a rotational encoder, a capacitive sensor for human machine interface (HMI), and an integrated microfluidic reactor with a built-in Joule heater for nanomaterial synthesis, as a few example applications. The methodology demonstrated herein shows a series of advances. Firstly, it facilitates programmed assembly of both functional and structural materials into the integrated 3D devices by a single apparatus, thus eliminating the requirement of many processing steps in different apparatuses. Secondly, it augments the versatility by direct laser processing of different functional materials with negligible precursor waste streams. Thirdly, FLI decouples the synthesis of the functional materials from FFF and DIW, thus it can pattern them in any predesigned locations of the 3D structures. Overall, the methodology described herein represents a step forward in the creation of integrated, multifunctional 3D objects with applications across electronics/sensors, human-machine interface (HMI), robotics, and functional microfluids.

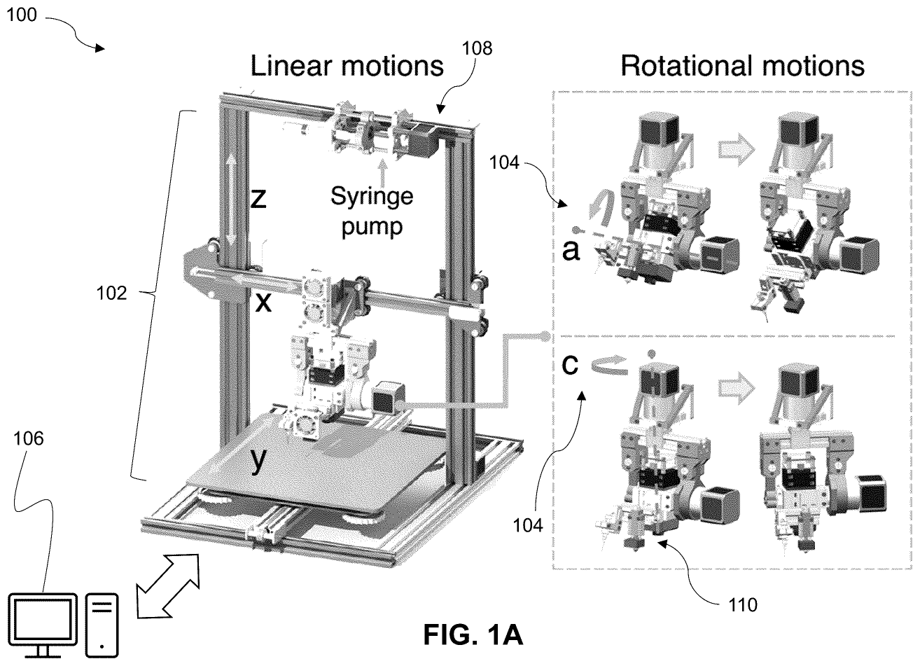

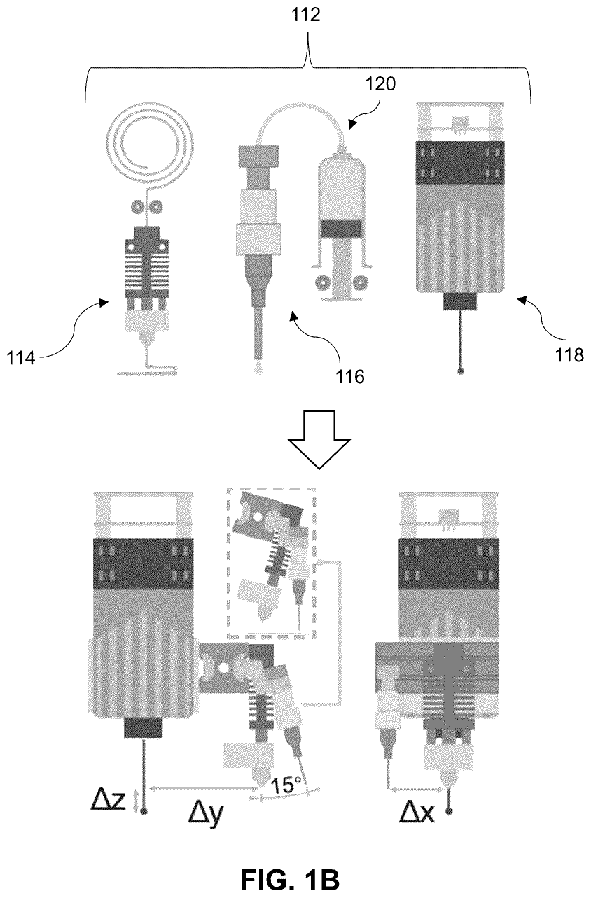

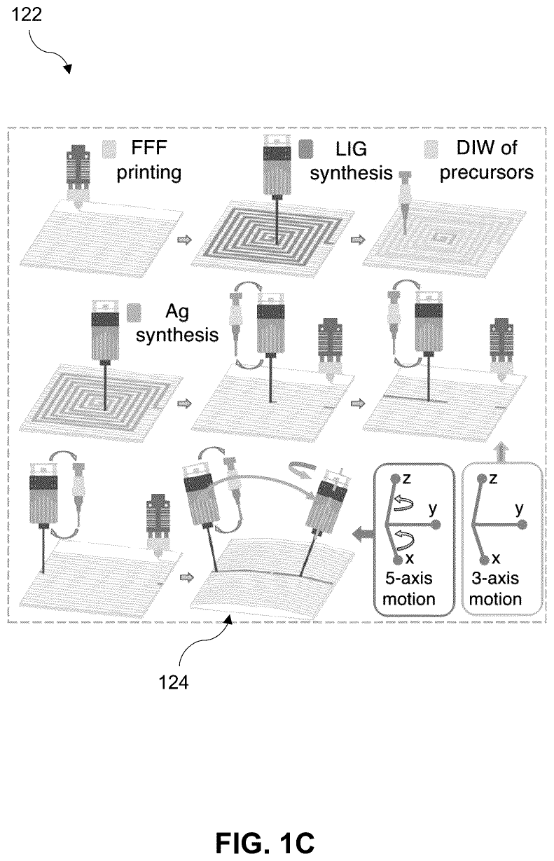

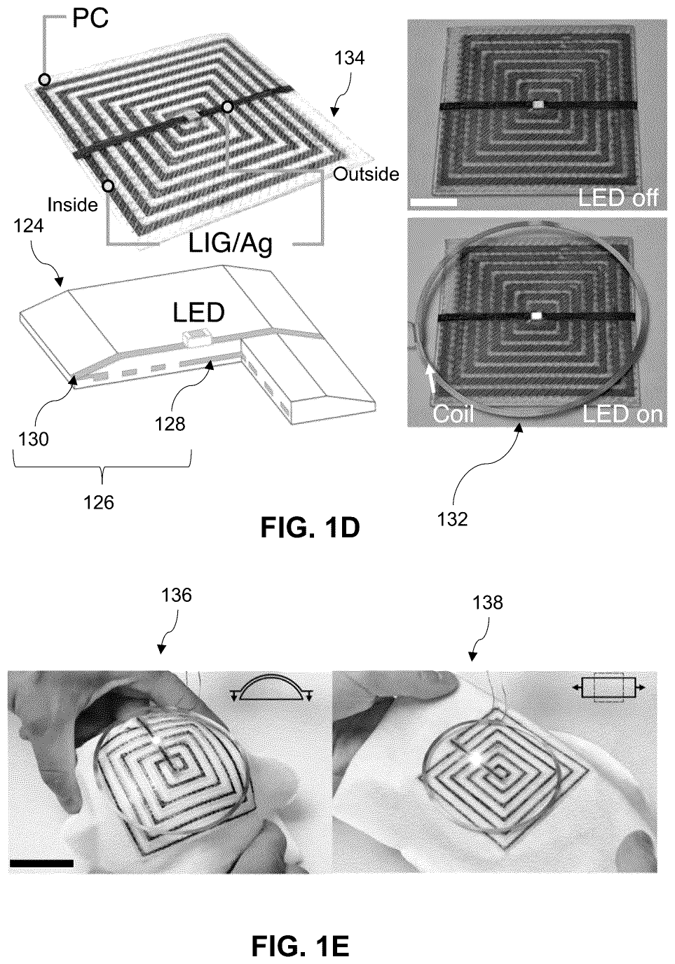

FIGS. 1A to 1E illustrate, for example, a schematic of an FMAP platform and a workflow of fabricating 3D devices by assembling structural and functional materials using FMAP according to one embodiment of the present disclosure.

FIG. 1A illustrates a schematic showing an FMAP platform 100 (or simply platform 100) including linear actuation system 102 and rotational actuation system 104, where platform 100 is in operative communication with a computer/computing system 106 (also referred to as a computing device, e.g., computing device 106) configured to provide control (e.g., computer-based control). FMAP platform 100 may also be referred to herein as a multi-axis actuation system. As shown in FIG. 1A, linear actuation system 102 provides for movement along x, y, and z axes, and rotational actuation system 104 provides for rotation about rotational axes “a” and “c.” FIG. 1A depicts FMAP with 5 degrees of freedom (DOF) (also referred to herein as 5-axis) by incorporating three linear motions (e.g., x-axis, y-axis, and z-axis via linear actuation system 102) and two rotational motions (e.g., about the “a”-axis and/or the “c”-axis via rotational actuation system 104). Various combinations of rails/tracks, motors and/or gear boxes may be implemented to facilitate motion and/or translation along/about the various axes. For example, one or more motors connected to one or more harmonic gear boxes provide sufficient torque for the rotational axes with precise movements. Some embodiments may include multiple (e.g., two) additional motors that control the extrusion of FFF and DIW. Various fans, e.g., for cooling, may be implemented as part of FMAP platform 100. FMAP platform 100 may include a print bed, and one or more extruders such as one or more syringe pumps 108 that may be implemented to dispense materials such as various fluids, such as melted filament materials, etc., and a hotend assembly 110. Hotend assembly 110 may include a nozzle connected to a heater block (e.g., for melting filament), and may range in size from 0.1 mm to as much as 2 mm or beyond depending on the application. The heater block may include a connected heater cartridge (e.g., with or without insulation around the block, to help preventing heat fluctuation). The heater cartridge may run through the heater block as the source of heat for hotend assembly 110. A thermistor may be positioned inside the heater block and read the temperature of hotend assembly 110. Hotend assembly 110 may also include a heat break and one or more cooling implements such as one or more heat sinks and/or fans (e.g., cooling fans), such as for cooling the heat break and/or for part cooling such as for PLA filaments.

FMAP platform 100 may further include (i) various end stops/limit switches, where end stops mark the home position of each axis (e.g., associated with a home position), and/or (ii) sensors such as (a) an auto level sensor, for example to measure where the low and high points are on bed to compensate for the differences (e.g., allowing printing on the surface evenly even if the bed is uneven) and/or (b) a filament sensor, to detect when filament runs out and capable of pausing the print. Additional examples of sensors that may be implemented as part of or in association with platform 100 include thermal sensors (e.g., thermocouples), light sensors (e.g., infrared (IR)/ultraviolet (UV) sensors), force sensors (e.g., load cells), optical/vision sensors (e.g., as part of cameras and/or other optical instrumentation capable of providing visual inspection during the fabrication process), flow sensors (e.g., for monitoring material flow), environmental sensors (e.g., for detecting environmental conditions such as moisture in the form of humidity), vibration sensors, and/or motion sensors (e.g., accelerometers). These sensors may be configured to provide real-time feedback to the computing device 106 for adjusting process parameters during fabrication. The process parameters may include parameters for monitoring and/or adjusting quantities such as speed, motion, material flow, and the like during fabrication. By implementing particularized sensors as part of FMAP, quality, precision, and the like can be better controlled, and, in some embodiments, in a dynamic matter where adjustments can be made on the fly during fabrication. For example, due to the complex integration of FFF, DIW, and FLI as part of FMAP as described herein, it is important to be able to accurately monitor each individual process including any sub-processes to ensure proper fabrication of engineered structures. The implementation of various sensors in connection with platform 100 provides for dynamic control of fabrication during FMAP and represents a significant improvement over conventional techniques.

For example, thermocouples and infrared sensors may be implemented to monitor nozzle and bed temperatures to ensure consistent thermal conditions, where, if the temperature drifts, computing system 106 can adjust heating elements of platform 100 accordingly. Force sensors such as load cells may be implemented as part of platform 100 to measure various forces such as extrusion force, bed leveling pressure, and/or nozzle application force, and may assist with detecting issues such as clogs, uneven surfaces, and/or over-extrusion, allowing components such as printing elements and/or other end effectors to be dynamically controlled via dynamic modifying of process parameters, such as parameters relating to feed rates and/or bed height. Optical and/or laser sensors may be implemented as part of platform 100 to verify fabrication aspects such as layer height and perform surface inspection, and be configured to detect issues such as warping, misalignment, and/or other defects as well as trigger corrective actions based on the detected issues. For example, a corrective action may be pausing or stopping fabrication so that a detected issue can be addressed (e.g., automatically via a computer-based correction scheme and/or via operator intervention). Flow sensors such as filament runout sensors may be implemented as part of platform 100 to detect when filament is about to run out or if there is a feeding issue (e.g., feeding inconsistently), which assists with preventing failed prints and allows for automatic pausing and/or feed rate adjustments. Environmental sensors such as humidity sensors may be implemented as part of platform 100 to monitor ambient conditions such as humidity and/or temperature, which can affect material properties, adherence, etc. Motion sensors such as vibration and/or accelerometer sensors may be implemented as part of platform 100 to track mechanical stability and component movement such as printer head assembly movement, movement of other end effectors, etc. For example, if a detected vibration exceeds a designated threshold, speed/acceleration of components may be controlled to slow down or otherwise adjust acceleration to maintain fabrication quality. Vision sensor systems such as cameras or other visual sensors may be implemented as part of a computer vision (e.g., machine vision) control scheme of platform 100 to inspect fabrication in real-time, comparing data corresponding to real-time inspection results to data from baseline and/or model parameters, and adjusting process parameters accordingly if deviations from the baseline/model parameters are detected. Computing device 106 may include input/output ports and/or other communication interfaces to enable data exchange between the various sensors and computing device 106, and may be programmed with adaptive algorithms (e.g., control algorithms) to enable real-time decision making as described herein, such as adjusting extrusion speed, temperature, laser strength/duration, component (e.g., end effector) movement, etc., to ensure quality and/or dynamically adjust parameters to optimize quality, with other benefits including reduced waste and other efficiencies.

Additionally, platform 100 may include various other components such as tubes (e.g., a Bowden tube) and the like that may be implemented for running filament, etc.

As described in more detail herein, FMAP platform 100 may be controlled via computer system 106 including hardware/software of computer system 106, which may include a dedicated controller that includes, for example, particularized firmware for running FMAP and/or other processes described herein. Additionally, FMAP platform 100 may have its own dedicated controller and control software/routines that can be controlled by and/or integrated with aspects of computer system 106.

FIG. 1B illustrates a schematic of end effectors for FFF, DIW, and FLI, as well as an installation offset between the end effectors. FIG. 1B depicts three end effectors 112: an FFF end 114 (e.g., FFF nozzle), a DIW nozzle 116, and a laser module 118, according to one embodiment, and configured as follows. Both the FFF and DIW nozzles are assembled with the laser module to save space. FFF end 114 is placed in parallel to laser module 118, while DIW nozzle 116 is installed alongside the FFF that is strategically rotated by a certain angle such as 15° counterclockwise from the z-axis. When operating the extrusion by DIW, the “a”-axis motor rotates 15° clockwise, aligning a DIW syringe 120 parallel to the z-axis, while FFF end 114 is rotated away. This configuration prevents contact between the extruded ink and the FFF end. The role of the laser module 118 is to convert the FFF printed materials into LIG and the DIW deposited ink into functional materials, such as semiconductors, metals, and metal oxides. In one embodiment, laser module 118 emits light at a wavelength of 450 nm with a maximum power of 5 W. While a laser wavelength of around 450 nm may be utilized for certain embodiments described herein, in other embodiments lasers with different properties (wavelength, power, and pulse length), such as CO₂ lasers and fiber lasers (with different wavelengths, e.g., ˜10 μm), may be employed. Certain embodiments described herein were created using a desktop FFF printer with a 300 mm×300 mm×300 mm build volume, however the present process is able to be adjusted to accommodate (e.g., printing) machines with varying build volumes as required. Also, more extruders for FFF and DIW may be added to realize even more flexible multimaterial assembly. Computer system 106, in conjunction with any controllers, processors, software, firmware, etc. of platform 100, may perform control of the various end effectors 112 to control (e.g., software control) fluid delivery, motion, rotation, etc., with precision.

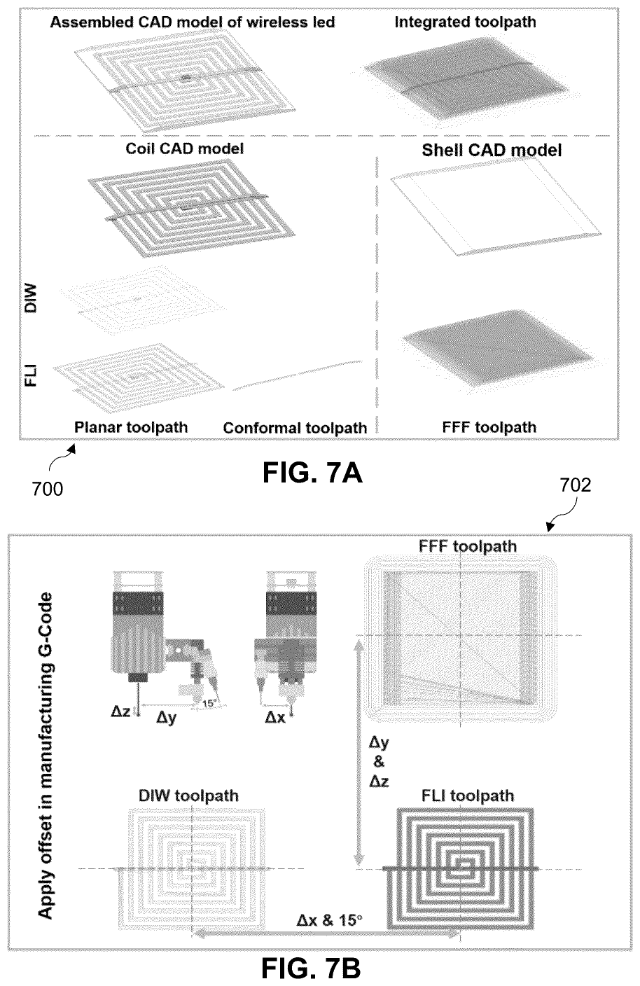

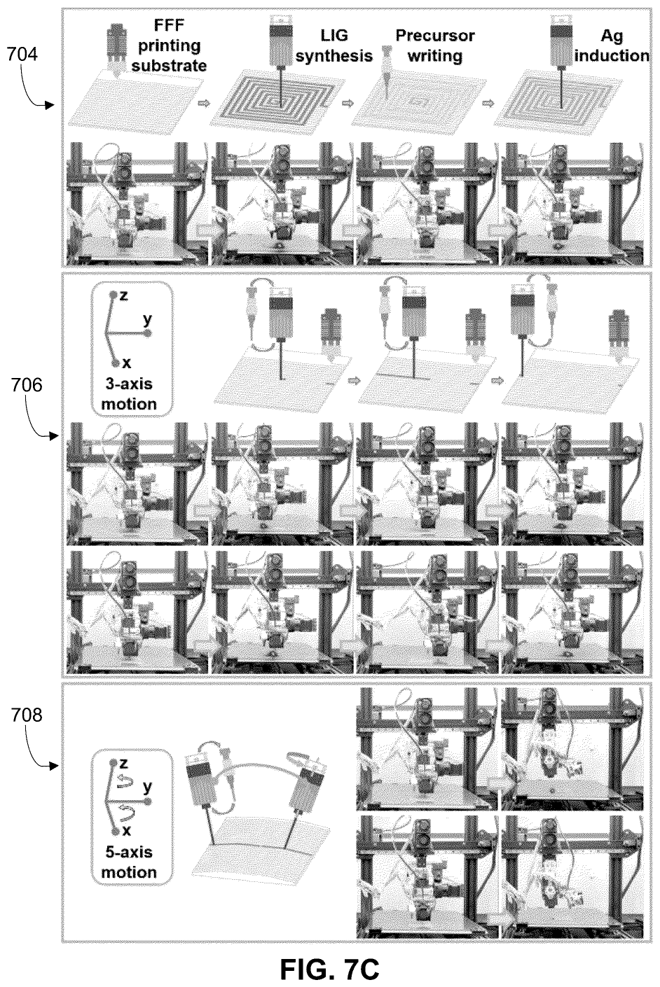

FIG. 1C illustrates a workflow 122 of fabricating a device such as a 3D wireless LED circuit with LIG (induced from PC) and Ag electrodes by FMAP. To distinguish the resulting materials from different processes, the FFF 3D printing results are colored light purple, LIG conductive traces are colored grey, the precursor of silver is colored light orange, and the silver is colored light blue. FIG. 1C illustrates fabrication of a 3D wireless LED 124, which is one example to explain the manufacturing workflow by FMAP (with additional details shown in FIGS. 7A-7C, described below). The process starts with FFF of a few layers of a PC structure. Then, the laser is turned on to selectively induce the PC to a LIG electrode. Next, an Ag precursor (e.g., silver citrate) is deposited onto the LIG electrode by DIW. Another laser induction converts the Ag precursor to Ag infiltrated in the LIG matrix to obtain a highly conductive LIG/Ag electrode, on top of which new PC layers are printed by FFF. During the laser induction, the laser is controlled in the five DOF to conformably pattern any complex geometry of the electrode onto the printed 3D structures. Computer system 106, in conjunction with any controllers, processors, software, firmware, etc. of platform 100, may perform (e.g., software) control to control the various fabrication aspects described herein. This includes but is not limited to design plans for device fabrication, and as well as actual control of such fabrication.

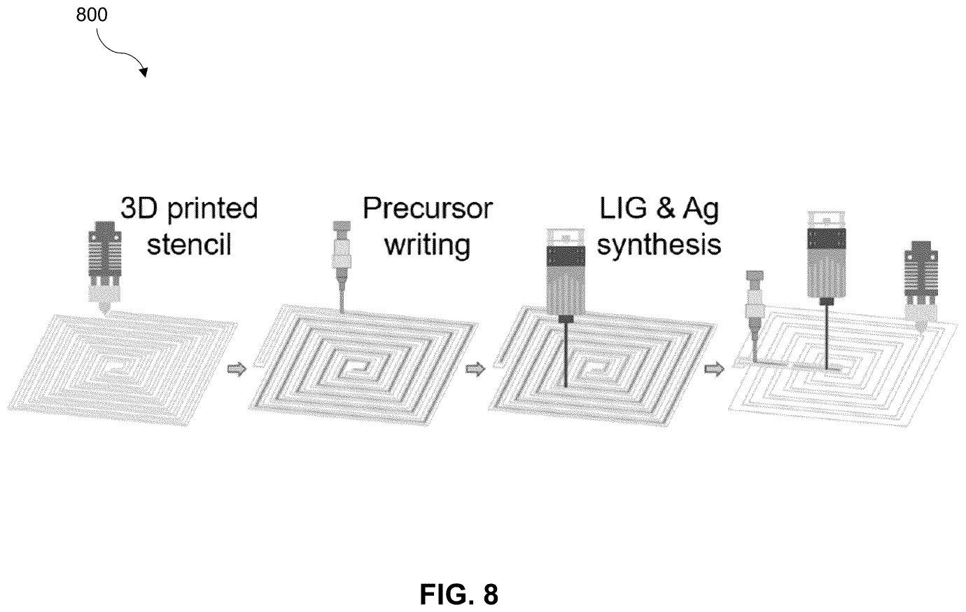

FIG. 1D illustrates a configuration scheme of a fabricated 3D wireless LED (e.g., 124 shown in FIG. 1C). FIG. 1D displays the fabricated wireless LED 124 corresponding to FIG. 1C, with a cross-section view illustrating the distribution of the conductive LIG/Ag electrode 126 inside the PC structure including an inside electrode portion 128 and an outside electrode portion 130. When powered with a charging coil 132, the fabricated LED is “on” as intended. To induce LIG from non-laser-convertible polymers such as TPU and PETG, an ink including lignin and silver citrate is first deposited on the selective positions of the FFF-printed TPU structure. Since the build plate is heated at 100° C., the solvent in the deposited ink evaporates rapidly. The laser induction on the ink can be operated immediately without stop, leading to formation of a LIG/Ag composite. This altered process is illustrated in FIG. 8, described below. Owing to the flexible nature of TPU and the LIG/Ag electrode, the same 3D wireless LED can be conformably fabricated onto a flexible cloth substrate 134.

FIG. 1E illustrates photographs 136 and 138 of a fabricated 3D wireless LED (e.g., 124 shown in FIG. 1C) with LIG (induced from lignin) and Ag electrodes on a cloth, being pressed onto a convex object (as shown in photograph 136) and stretched (as shown in photograph 138), where the scale bar shown in photograph 136 of FIG. 1E represents a scale of 10 mm. FIG. 1E illustrates that the fabricated flexible 3D LED maintains good lighting performance when wirelessly powered.

In addition to Ag, other materials may be synthesized via laser induction to afford diverse functionalities of the 3D structures. For instance, Fe can be incorporated for magnetism. Energy-dispersive spectrometry (EDS) may be conducted to analyze the spatial distribution of the synthesized metals (Ag, Fe, Co, and Ni) and a metal oxide (CuO) within LIG induced from different polymers (PC and PETG).

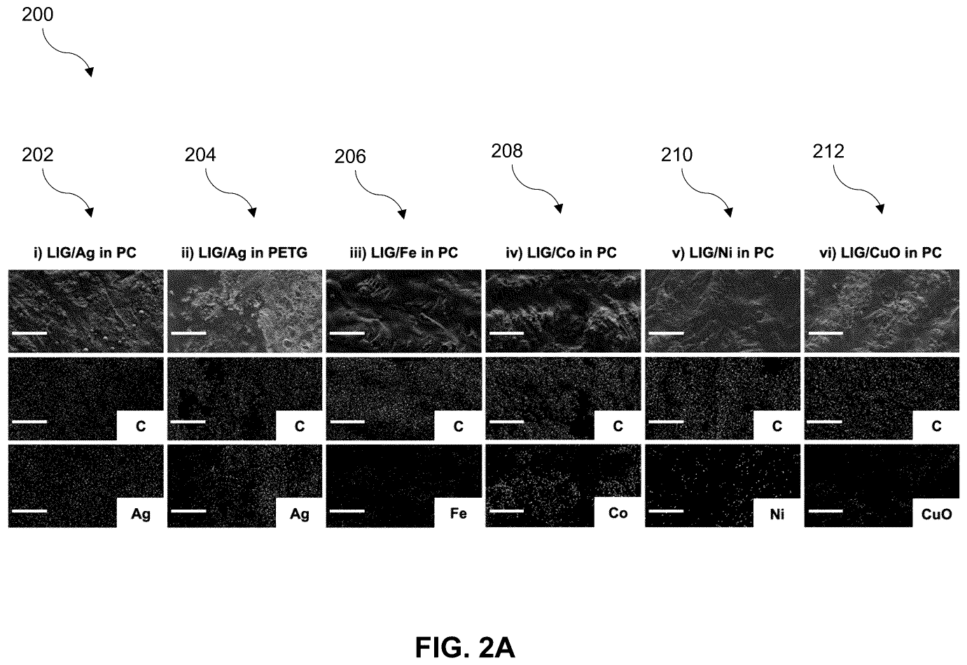

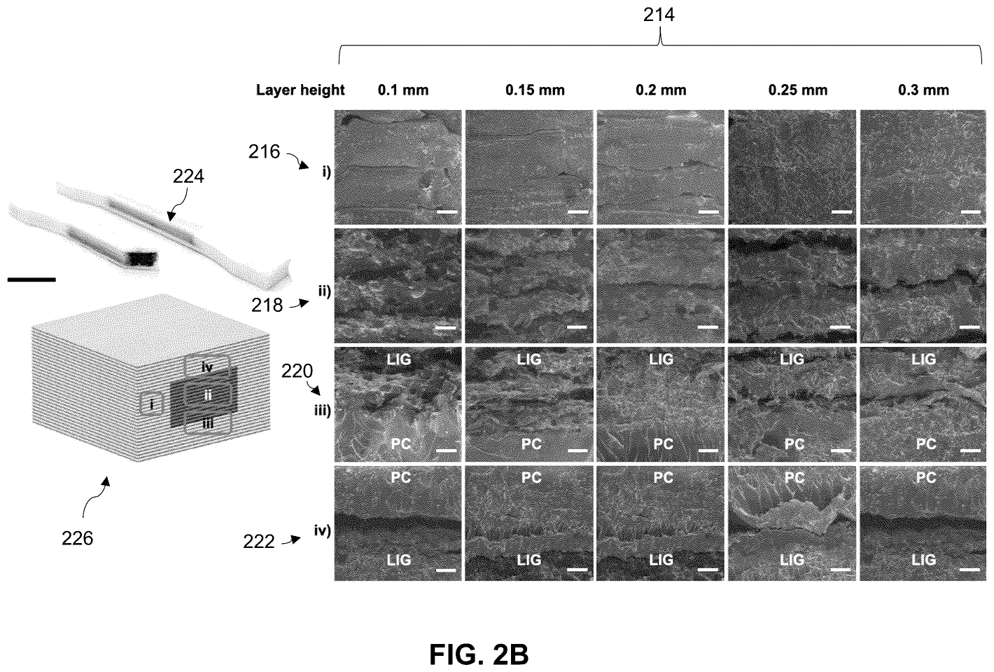

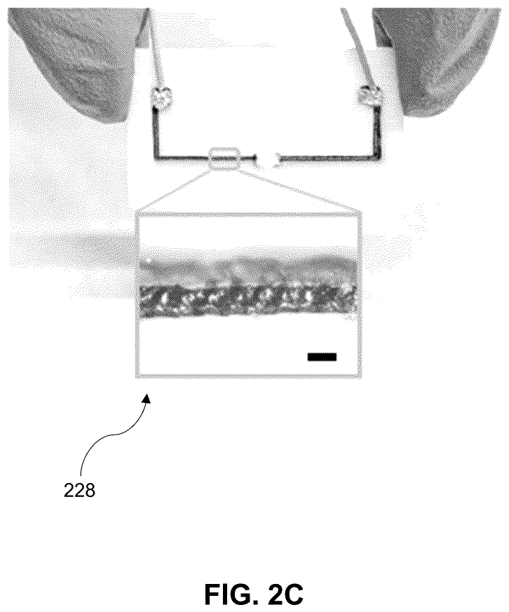

FIGS. 2A-2C illustrate microscopic characterizations 200 of metals and metal oxides in LIG induced from various polymers according to one embodiment of the present disclosure.

FIG. 2A illustrates scanning electron microscopy (SEM) and EDS images of metals and metal oxides in LIG induced from various polymers: (i) LIG/Ag in PC (e.g., 202 shown in FIG. 2A); (ii) LIG/Ag in PETG (e.g., 204 shown in FIG. 2A); (iii) LIG/Fe in PC (e.g., 206 shown in FIG. 2A); (iv) LIG/Co in PC (e.g., 208 shown in FIG. 2A); (v) LIG/Ni in PC (e.g., 210 shown in FIG. 2A); (vi) LIG/CuO in PC (e.g., 212 shown in FIG. 2A), where the scale bar represents 20 μm. FIG. 2A illustrates that LIG is highly porous. The synthesized metals and metal oxides are in a form of nanoparticles (NPs) well dispersed inside the LIG matrix as depicted in the elemental mapping of the composites.

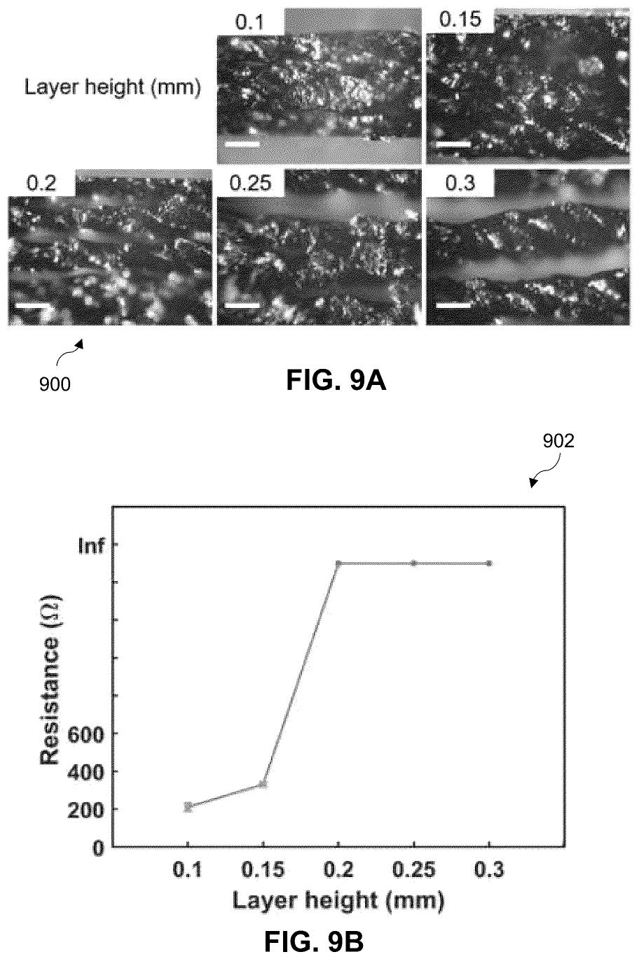

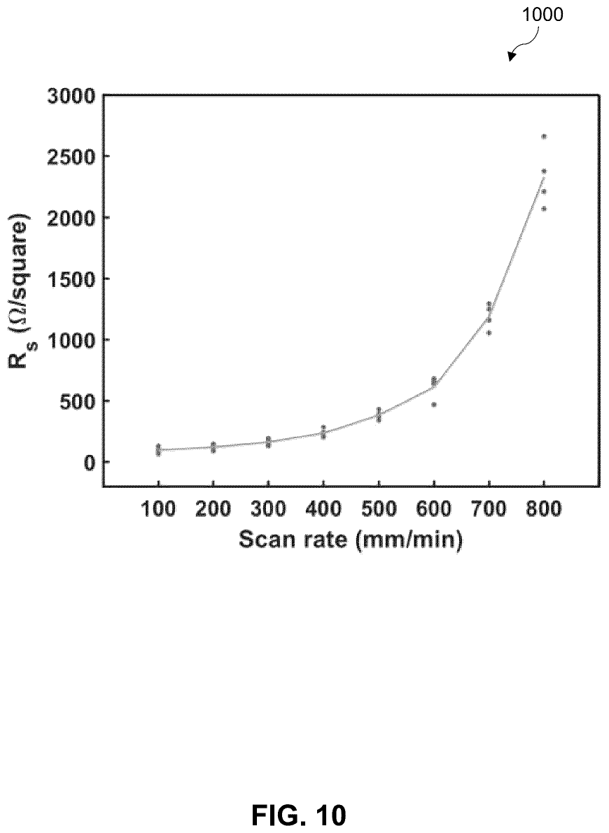

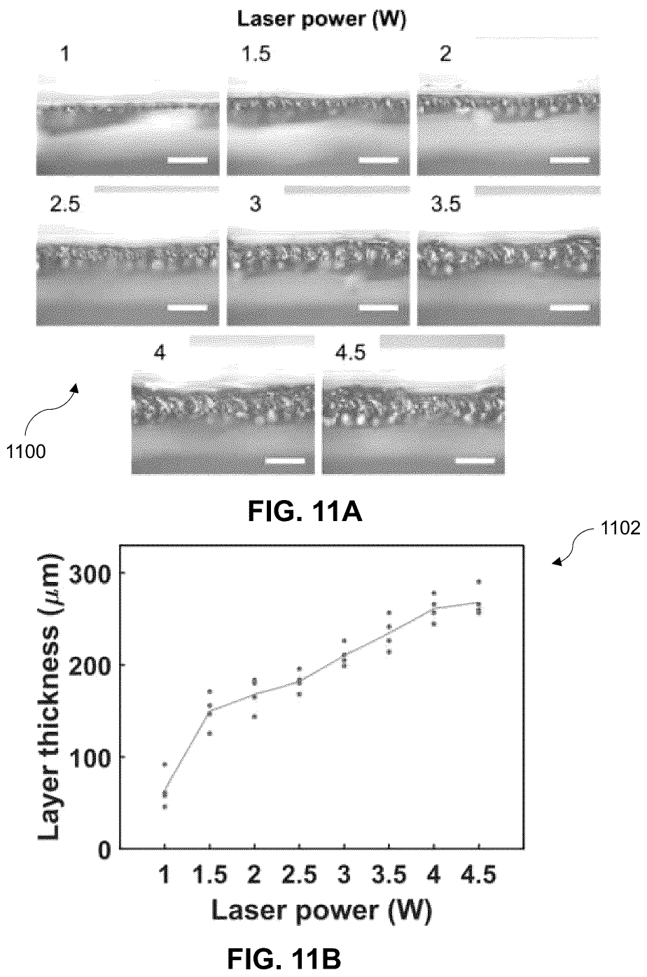

FIG. 2B illustrates cross-sectional SEM images 214 collected from four regions 216-222 of LIG embedded 3D structures such as structure 224 including cross-section view 226. More specifically, FIG. 2B illustrates cross-sectional SEM images of LIG produced from PC printed with five different layer heights. They are imaged from four different locations of the 3D structures (denoted with Roman numerals i) (e.g., 216 shown in FIG. 2B), ii) (e.g., 218 shown in FIG. 2B), iii) (e.g., 220 shown in FIG. 2B), and iv) (e.g., 222 shown in FIG. 2B)), where the scale bar represents 10 mm. The printing layer heights may vary from 0.1 to 0.3 mm, with the laser (e.g., of laser module 118) operated at a power such as 2.5 W, in a focused status, and with a set scan rate such as a scan rate of 300 mm/min. The examined regions 216-222 encompass: a pure polymer (e.g., 216), a LIG region (e.g., 218), an area where LIG overlays a polymer (e.g., 220), and a polymer region with LIG underneath (e.g., 222). Images 214 show a clear polymer gap in between the LIG layers when the layer height exceeds 0.15 mm, implying an incomplete conversion of the entire layer into LIG. Additional details are shown by the result shown in FIGS. 9A and 9B, described below, where the electrical resistance in the z-axis direction is dramatically increased when the layer height exceeds 0.15 mm. FIG. 10, described in more detail below, shows that a slower scan rate results in a smaller sheet resistance, reaching the smallest value of 98.2 Ω/sq at 100 mm/min. The relationship between the LIG thickness and laser power is revealed in FIGS. 11A and 11B, described below. This shows that as the laser power rises, the LIG thickness increases.

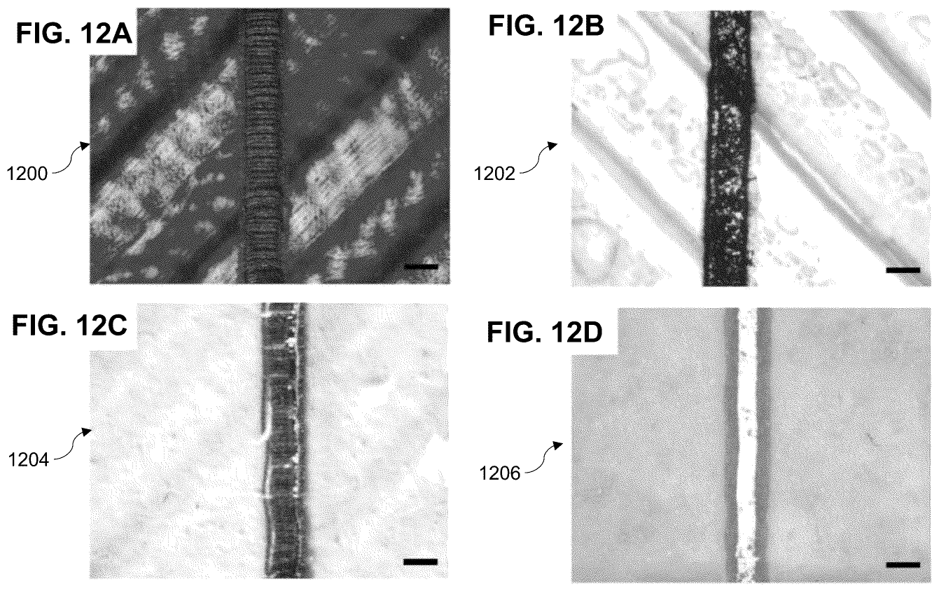

FIG. 2C illustrates a photograph 228 of a LIG/Ag electrode to light up an LED, where the scale bar represents 200 μm. More specifically, FIG. 2C illustrates a laser induction resolution sample (e.g., via photograph 228) where a conductive LIG trace with a width of 200 μm can effectively power an LED. FIGS. 12A-12D, described in more detail below, indicate that the linewidth of the laser induced functional materials varies based on the precursors and laser parameters with the best one achieving ˜100 μm in the silver. In this example, tensile testing specimens (dimensions: 25 m×3 mm×1 mm) with embedded LIG in the center (dimensions: 25 mm×2 mm×0.4 mm) were produced by FMAP, and the PC was printed with the layer heights of 0.1-0.2 mm.

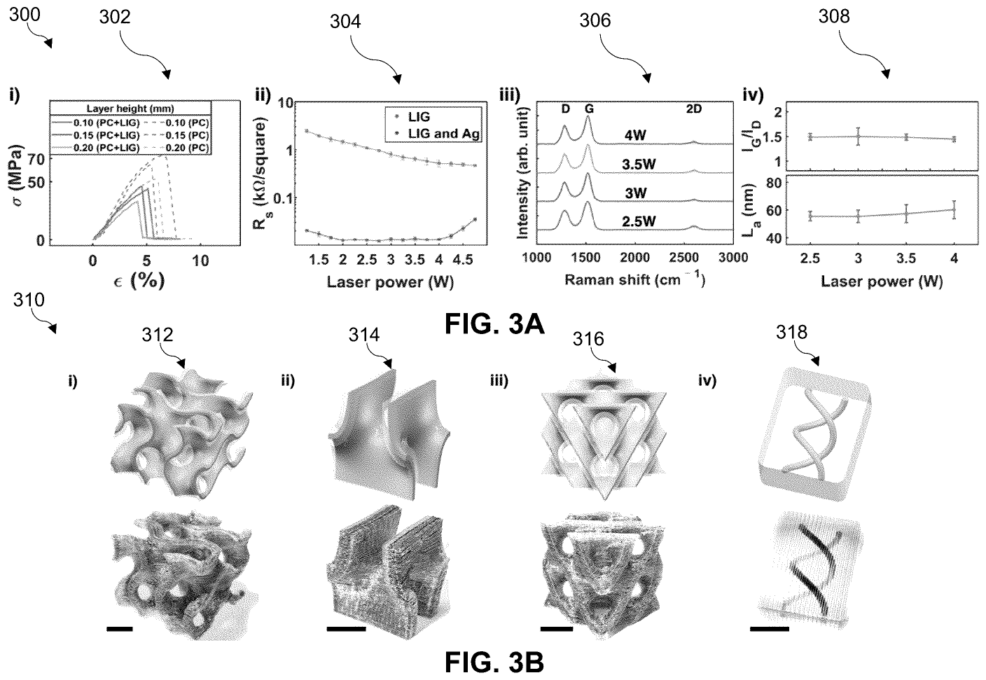

FIGS. 3A and 3B illustrate material property characterizations according to one embodiment of the present disclosure.

FIG. 3A illustrates plots 300 of properties of LIG and LIG/Ag composite in PC: (i) stress-strain curves (e.g., plot 302 shown in FIG. 3A); (ii) electrical conductivity of LIG and LIG/Ag composite produced at different laser powers (e.g., plot 304 shown in FIG. 3A), where error bars indicate the standard deviation obtained from 5 sheet resistance measurements; (iii) Raman spectra of LIG produced at different laser powers (e.g., plot 306 shown in FIG. 3A); and (iv) statistical analysis on the ratios of IG/ID (upper panel) and calculated average LIG domain sizes (lower panel) (e.g., plot 308 shown in FIG. 3A), where error bars indicate the standard deviation obtained from 10 Raman spectra.

FIG. 3B illustrates different 3D structures 310 printed from PC with encased LIG inside: (i) a gyroid (e.g., 312 shown in FIG. 3B); (ii) a Schwarz P surface (e.g., 314 shown in FIG. 3B); (iii) a schwarz diamond surface (e.g., 316 shown in FIG. 3B); and (iv) a helix (e.g., 318 shown in FIG. 3B), where the scale bar represents 10 mm.

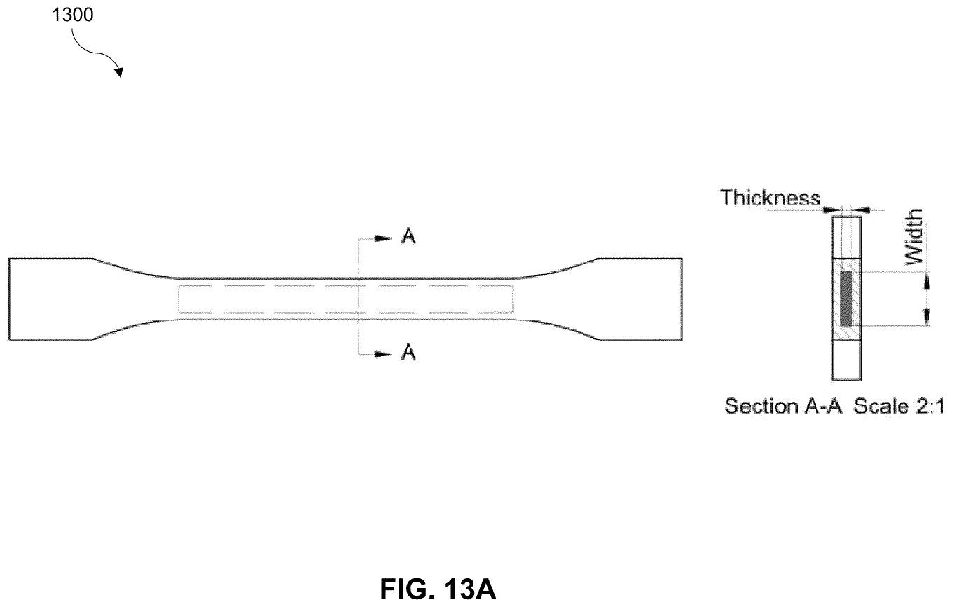

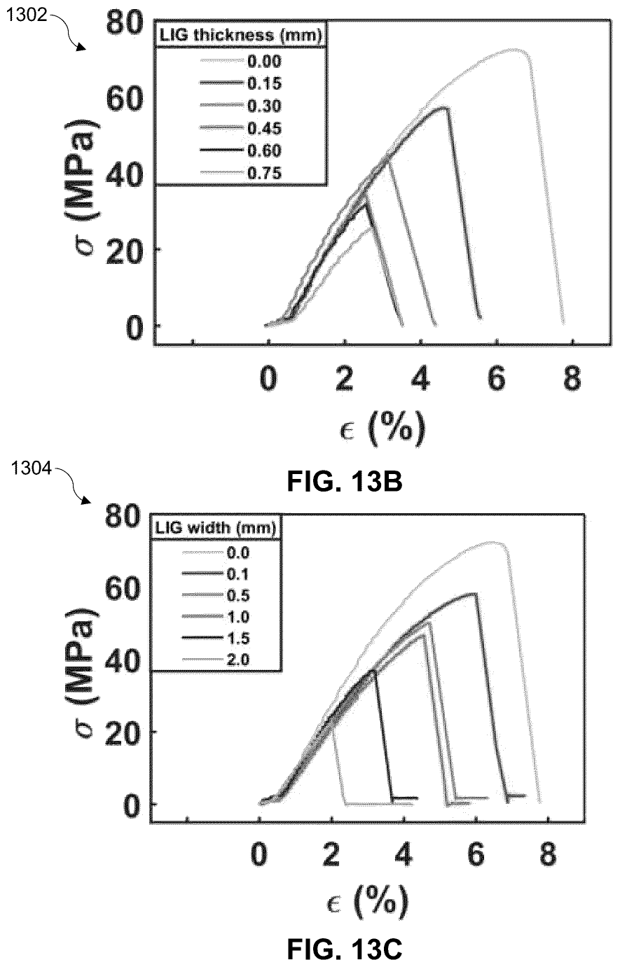

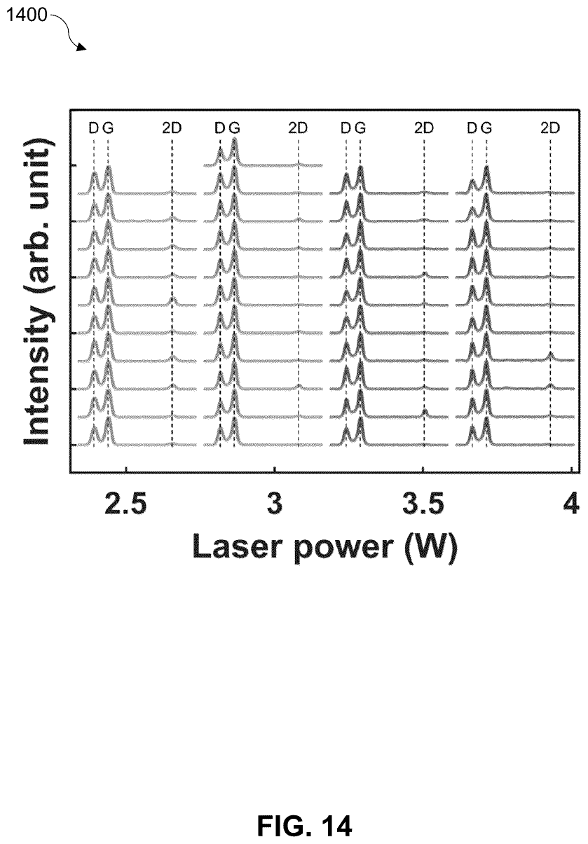

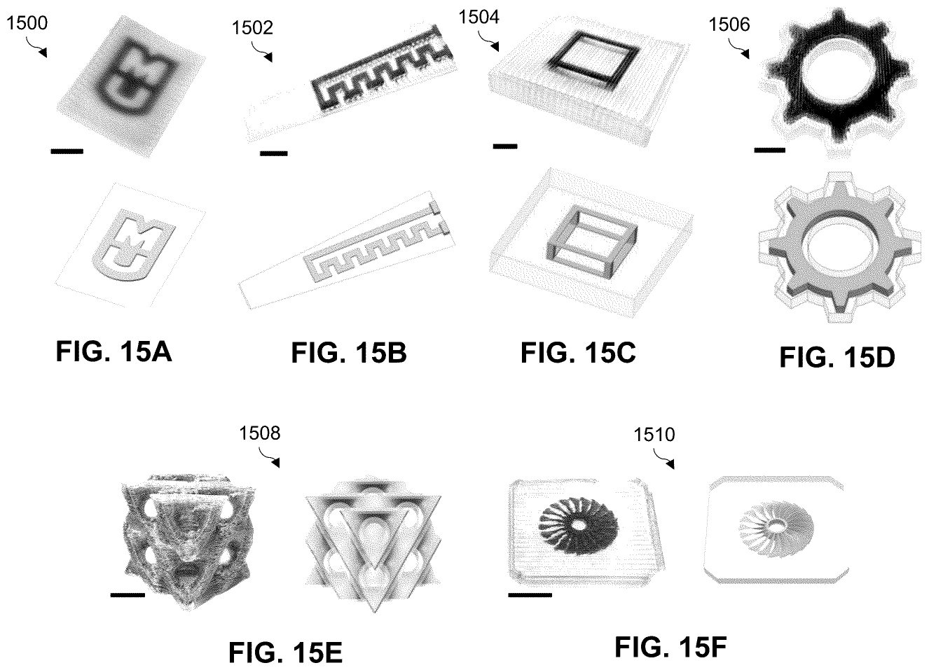

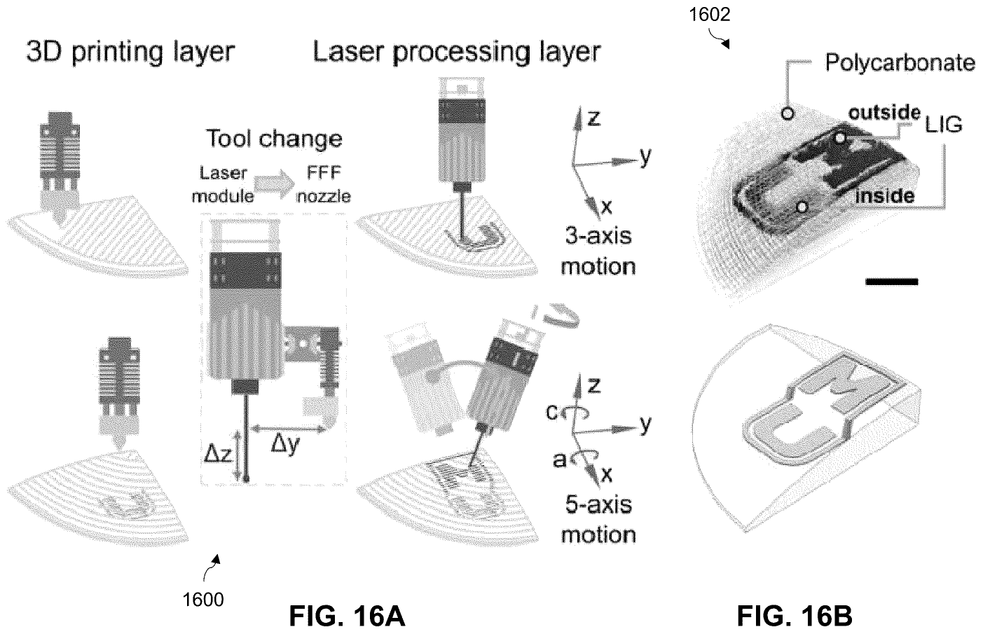

FIGS. 3A and 3B illustrate tensile strengths all exceeding 35 MPa, which is compatible to pure PC specimens, indicating well-maintained mechanical properties even if the PC is partially converted to LIG. Furthermore, in testing scenarios, tensile testing was performed on specimens embedded with LIG. The LIG dimensions were varied while keeping laser power and printing layer height constant. FIGS. 13A-13C, described in more detail below, show that as the LIG thickness and width increases, respectively, both the tensile strength and fracture strain decrease. FIG. 3A at plot 304 (e.g., ii) illustrates that the sheet resistance of LIG/Ag is superior to that of LIG, reaching as low as 12.36 Ω/sq at a laser power of 2.75 W. Raman spectra were collected from LIG formed from PC using four laser powers (see FIG. 14, described in more detail below). All displayed characteristic peaks at ˜1330 cm⁻¹, ˜1580 cm⁻¹, and ˜2700 cm⁻¹, corresponding to the D, G, and 2D bands of a graphitic material, respectively (FIG. 3A at plot 306 (e.g., iii)). The calculated intensity at G and D bands (I_{G}/I_{D}) ratio is close to 1.5, indicating a low defect level (upper panel of plot 308 of FIG. 3A (e.g., iv)). Crystallinity sizes (La, in nm), deduced from the I_{G}/I_{D} ratios, reach >60 nm at a laser power of 2.5 W (lower panel of plot 308 of FIG. 3A, e.g., iv). To showcase the potential of FMAP, complex 3D structures with spatially patterned LIG were fabricated. These included a gyroid, a Schwarz P surface, a spaceship, and a helix structure (see FIG. 3B). The versatility in fabricating complex 3D functional patterns within or on the surfaces of the printed 3D structures was further demonstrated by creation of an “MU” LIG logo enveloped with a PVDF shell, an airfoil structure embedded with LIG, a 3D lattice embedded within a cuboid, a 3D LIG gear, a 3D LIG fan (see FIGS. 15A-15F, describer in more detail below), and a 3D LIG “MU” logo with the “U” part enveloped inside PC and the “M” part patterned on the outer surface of the structure (see FIGS. 16A and 16B, described in more detail below).

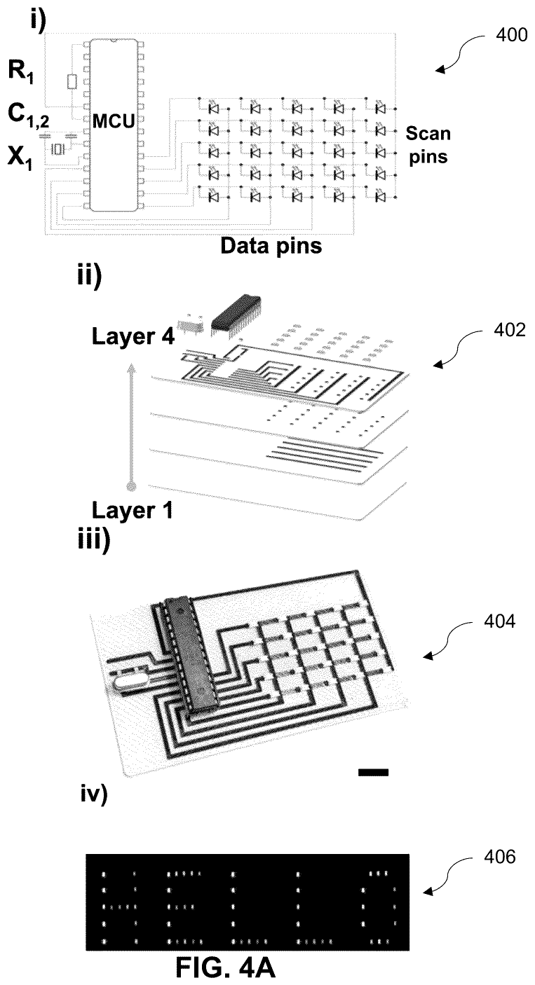

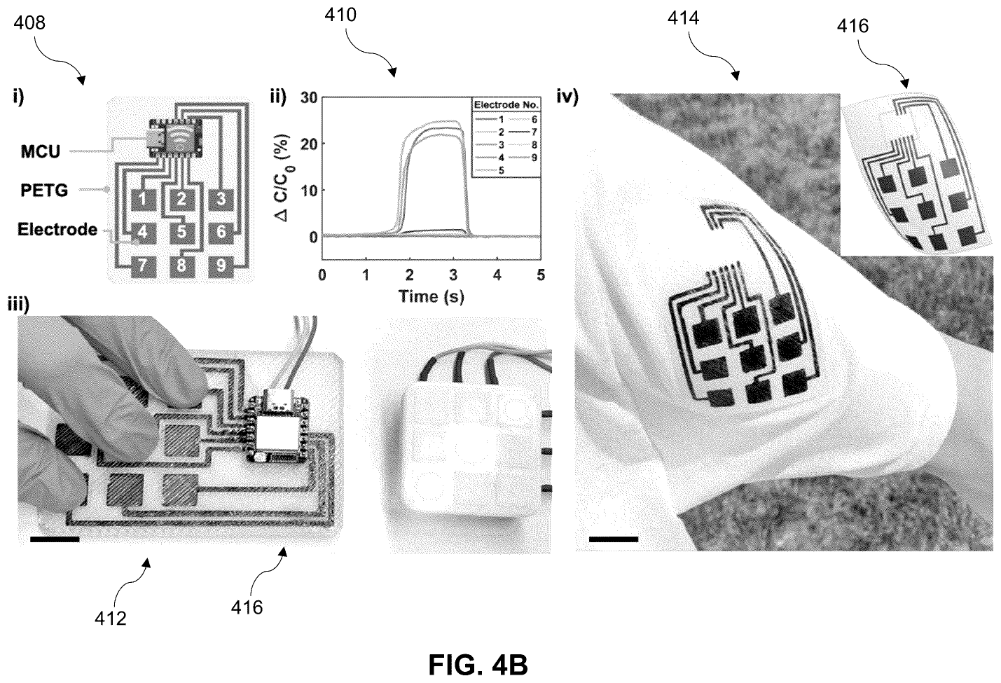

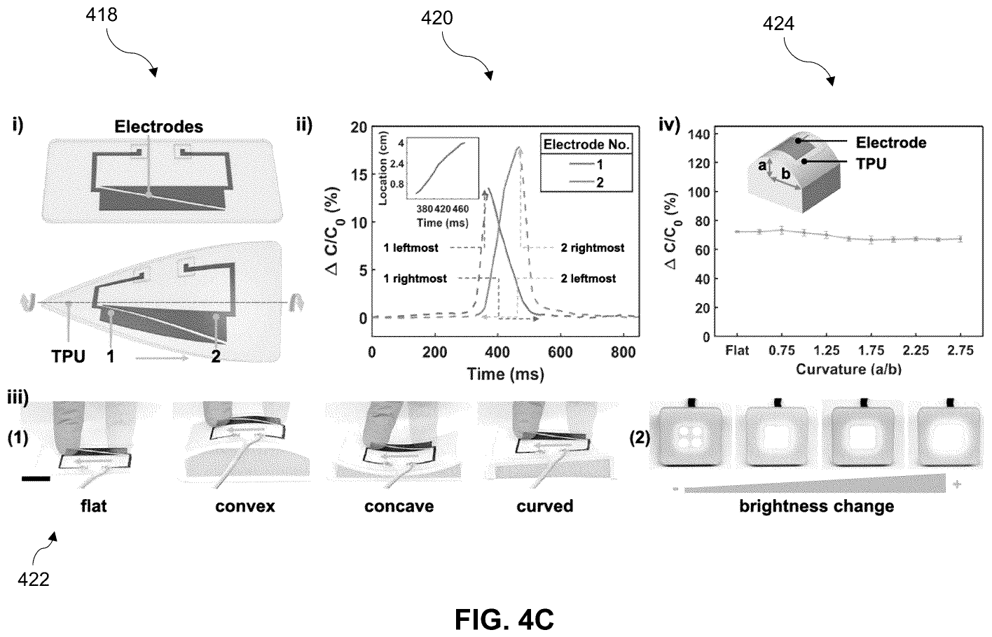

FIGS. 4A-4C illustrate functional materials used as conductive electrodes for PCBs according to one embodiment of the present disclosure. More specifically, FIGS. 4A-4C illustrate aspects of fabrication of a crossbar circuit for an LED array and a self-capacitance touch input device, by FMAP. A crossbar circuit is a type of a grid-like architecture that uses crossed electrode lines in separate vertical layers. Intersections of these lines create nodes to which devices are connected. A crossbar circuit for LEDs offers an advantage by addressing an individual LED, thus increasing device density and enhancing the overall energy efficiency of the LED display. Examples include a crossbar circuit for an LED display and self-capacitance sensors on both rigid and flexible substrates for HMI, which, in testing scenarios were demonstrated to show the potential of FMAP in fabricating integrated 3D electronic devices. This shows that compared to traditional PCB fabrication processes that involve chemical etching, the FMAP techniques described herein simplify the procedures with material utilization of ˜100%.

FIG. 4A illustrates diagrams 400-406 corresponding to a crossbar circuit embodiment of the present disclosure. Diagram 400 (e.g., at i) in FIG. 4A) illustrates a schematic showing the equivalent circuit of the crossbar LED array and its onboard microchip controller. Diagram 402 (e.g., at ii in FIG. 4A) illustrates an exploded view showing the layer-by-layer electrode structure of the crossbar circuit for the LED array. Diagram 404 (e.g., at iii in FIG. 4A) illustrates a photograph of the crossbar LED array and its onboard microchip on PC with LIG/Ag as the electrode, where the scale bar represents 2 mm. Diagram 406 (e.g., at iv) in FIG. 4A) illustrates a photograph showing the LED array displaying letters of “HELLO.”

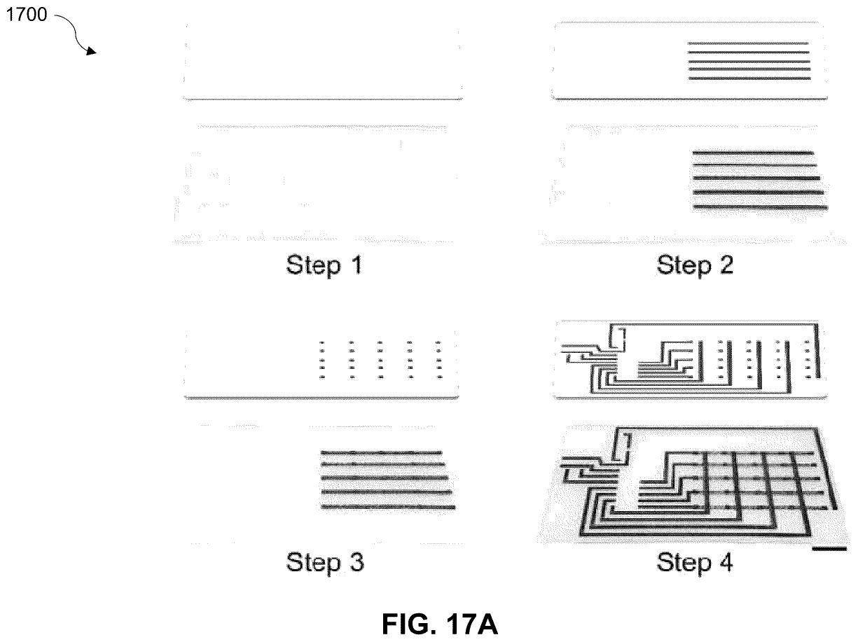

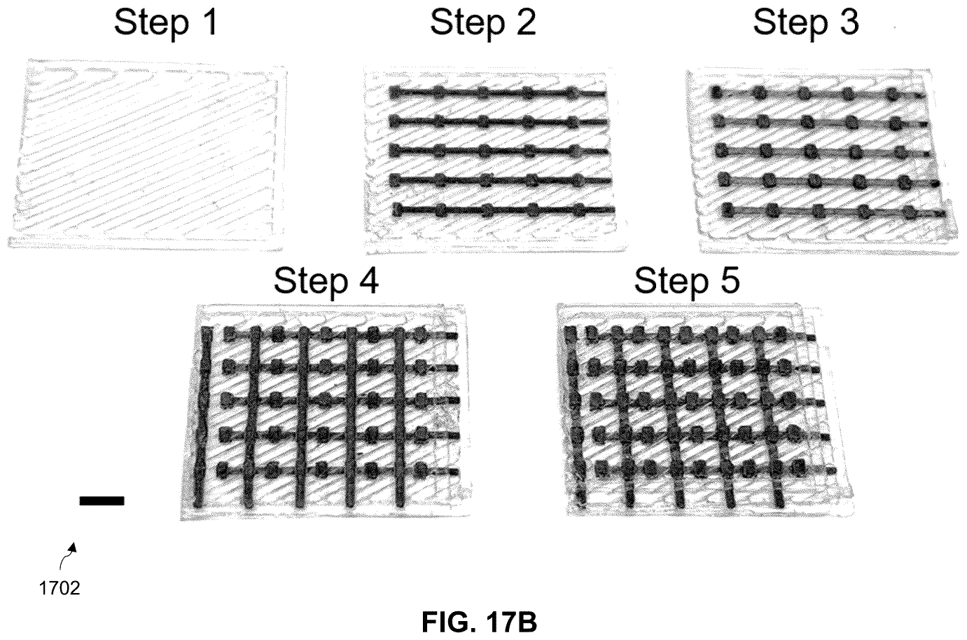

Further regarding FIG. 4A, diagram 400 illustrates equivalent circuit for a 5×5 LED array and its controller is presented via diagram 400 in FIG. 4A (e.g., at i) in FIG. 4A), where the anodes and cathodes of the LEDs are connected to the bottom and top electrode lines which are insulated by the printed polymers. To fabricate such a crossbar array, multiple layer operations by FMAP as shown in FIG. 4A at diagram 402 (e.g., at ii) in FIG. 4A) (and in FIGS. 17A and 17B, described in more detail below) are deployed. This begins with the FFF printing of a bottom PC layer, which is selectively induced to LIG/Ag electrode lines. Then, the laser selectively induces LIG/Ag electrodes and connection points for the anodes of the LEDs to connect to the bottom electrode. After the encapsulation layer is superimposed over the electrodes by FFF, another laser induction of the top LIG/Ag electrode lines and respective connection points follows for the cathodes of the LEDs to connect to the top electrodes. Finally, the LEDs, microcontroller, resistors, capacitors, and crystal are assembled to the nodes to obtain a 5×5 crossbar LED array (see FIG. 4A at diagram 404 (e.g., at iii) in FIG. 4A). This demonstrates a capability of controlling an individual LED to display patterns of “HELLO” (see FIG. 4A at diagram 406 (e.g., at iv) in FIG. 4A).

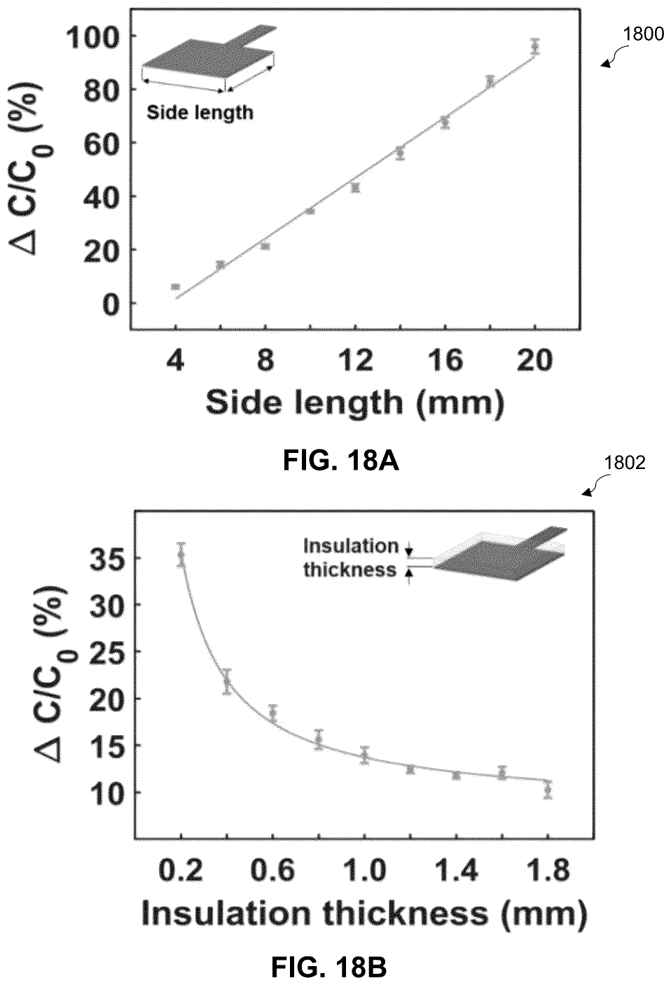

FIG. 4B illustrates a diagram 408, a plot 410, a photograph 412, and a photograph 414 in connection with an HMI embodiment of the present disclosure, particularly a touchpad 416 embodiment. Use of touch as an input method for HMI has gained much popularity. HMI enables users to interact with electronic devices through physical contact with touch-sensitive sensors, e.g., a self-capacitive sensor which is commonly employed due to its ease of implementation and high reliability, and may include nine conductive electrodes, and the environment serves as a virtual ground. When an object touches the sensing electrode, it modifies the electric field around the electrode, leading to a change in the capacitance. In the context of the present disclosure, fabrication of a touchpad with a plurality of (e.g., nine) capacitive sensing electrodes begins with FFF printing a PETG stencil for all electrodes (see FIG. 4B at diagram 408, e.g., at i)). Then an LIG/Ag precursor is deposited by DIW into the stencil followed by the laser induction to form the electrodes. Finally, an encapsulation layer is applied over the electrodes by FFF. Then the electrodes are connected to a microcontroller for sensing and wireless communication control. When three fingers touch the Nos. 1, 5 and 9 electrodes, they show >20% change in their capacitances while others exhibit negligible change (see FIG. 4B at plot 410, e.g., at ii)). This touchpad can be used to control other devices such as a LED array through Bluetooth low energy (BLE) (see FIG. 4B at photograph 412, e.g., at iii)). Paramount parameters such as the encapsulation thickness and electrode dimensions that affect the capacitance response were investigated. The results are concluded in FIGS. 18A and 18B (described in more detail below). If using a flexible polymer such as TPU, a flexible touchpad 416 can be fabricated (see FIG. 4B at photograph 414, e.g., at iv) in FIG. 4B).

Further regarding FIG. 4B, diagram 408 (e.g., at i) in FIG. 4B) illustrates a schematic showing a layout of touchpad 416, featuring a PETG substrate, 9 LIG/Ag electrodes, and a microcontroller. Plot 410 (e.g., at ii) in FIG. 4B) capacitive response and corresponding LED lights when the Nos. 1, 5 and 9 electrodes were touched during testing. Photograph 414 (e.g., at iv) in FIG. 4B) shows electrodes made from LIG and Ag embedded in TPU printed on textile, where the scale bar represents 10 mm.

FIG. 4C illustrates a slider embodiment of the present disclosure. Regarding FIG. 4C, in one test scenario, a slider illustrated in diagram 418 and based on two LIG/Ag triangular electrodes was fabricated using TPU as the structure material (see diagram 418 of FIG. 4C, e.g., i). When the finger slides from the leftmost end to the rightmost end of the slider, the overlapping area between the finger and electrode 1 initially reaches its maximum, then gradually decreases. Consequently, the capacitance of electrode 1 first reaches its maximum and then decreases, while electrode 2 follows an opposite trend with gradual increase to the maximum. By subtracting the normalized data of electrode 1 from electrode 2, the capacitance change of the two electrodes is quite linear to the finger locations (see inset of plot 420 of FIG. 4C, e.g., at ii). Since the slider is flexible, it can conform to the flat, concave, convex, and curved surfaces (see diagram 422 of FIG. 4C, e.g., at iii). With the determined finger position serving as a continuous input signal, it can be used to control the brightness of LEDs (see diagram 422 of FIG. 4C, e.g., at iii). The scale bar in diagram 422 represents 10 mm. In testing, the effect of the curvature on the sensor performance was studied. Plot 424 of FIG. 4C (e.g., at iv) shows that the capacitance change only slightly decreases from 73.4% to 66.6% as the bending curvature increases from 0 to 2.75, highlighting the high flexibility of the device.

Further regarding FIG. 4C, diagram 418 (e.g., at i) in FIG. 4C) illustrates a layout of a slider featuring two LIG/Ag triangular electrodes packaged inside TPU. As a finger slides from Electrode 1 to Electrode 2, the triangular electrodes facilitate a linear change in contact area on both electrodes, resulting in a linear change in capacitance. Plot 420 (e.g., at ii) in FIG. 4C) illustrates a capacitive response of sliders conformed to four types of surfaces as the finger moves between two ends for controlling brightness of a LED. Plot 424 (e.g., at iv) in FIG. 4C) illustrates a capacitance change of the slider under different bending curvatures, where the error bars indicate the standard deviation obtained from >10 capacitance measurements.

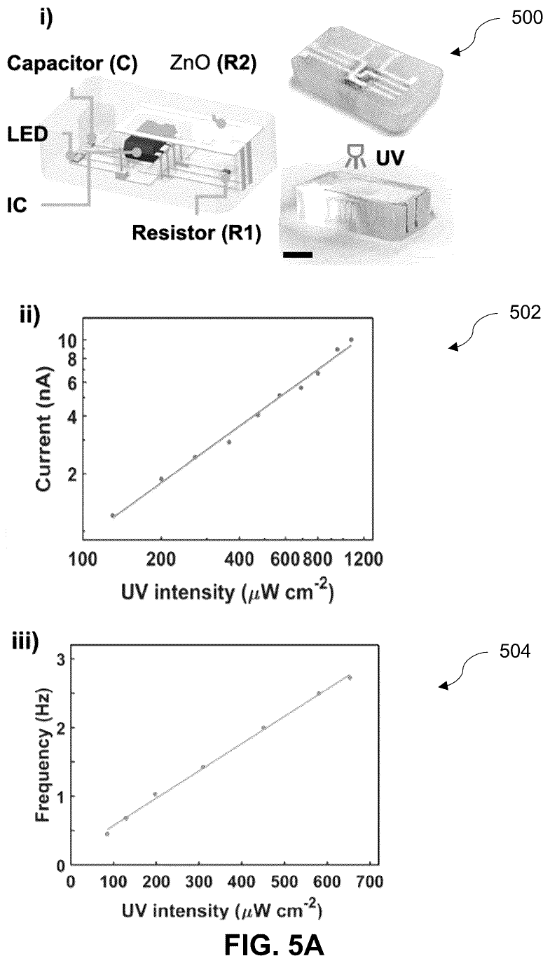

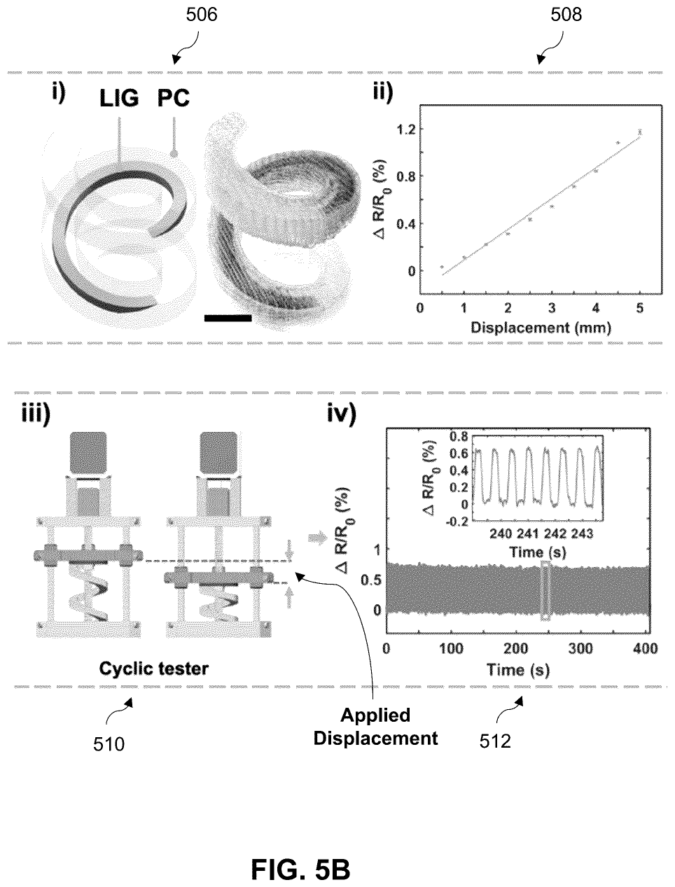

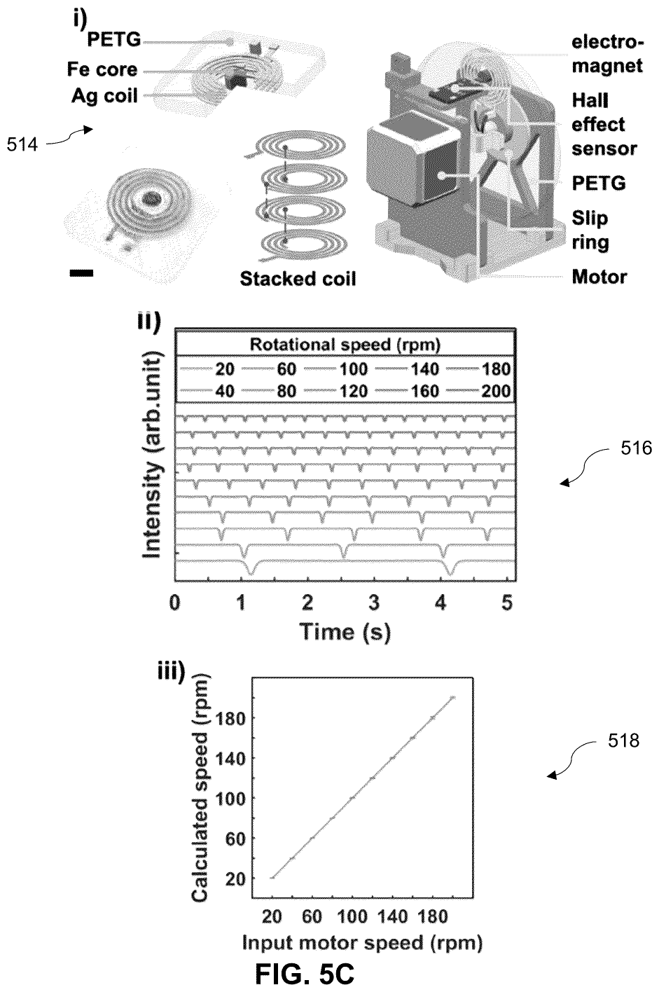

FIGS. 5A-5C illustrate fabrication of 3D engineered structures with integrated functional devices by FMAP according to one embodiment of the present disclosure.

Regarding FIG. 5A, diagram 500 (e.g., at i) in FIG. 5A) illustrates a schematic of an integrated UV sensor with electrical components, a photograph of the as-fabricated device and the device under UV light, where the scale bar represents 10 mm. Plot 502 (e.g., at ii) in FIG. 5A) illustrates photocurrents vs. UV light intensities at a bias of 3 V. Plot 504 (e.g., at iii) in FIG. 5A) illustrates an on-off frequency as a function of UV intensity.

Regarding FIG. 5B, diagram/photograph 506 (e.g., at i) in FIG. 5B) illustrates a schematic and a photograph of a spring with a PC shell and a LIG core, where the scale bar represents 10 mm. Plot 508 (e.g., at ii) in FIG. 5B) illustrates LIG resistance change as a function of displacement, where the error bars indicate the standard deviation obtained from 5 resistance measurements. Diagram 510 (e.g., at iii) in FIG. 5B) illustrates a scheme showing cyclic testing on the spring. Plot 512 (e.g., at iv) in FIG. 5B) illustrates evolution of resistance change in 640 loading-unloading cycles.

Regarding FIG. 5C, diagram/photograph 514 (e.g., at i) in FIG. 5C) illustrates a schematic and a photograph of a micro electromagnet, its 4-layer coil structure, and its application as an encoder for rotational speed measurement, where the scale bar represents 10 mm. Plot 516 (e.g., at ii) in FIG. 5C) illustrates a Hall effect sensor response data at different motor speeds. Plot 518 (e.g., at iii) in FIG. 5C) illustrates a plot of the rotation speeds calculated from the Hall effect sensor response data versus the input motor speeds, where the error bars indicate the standard deviation obtained from >20 rotational speed measurements.

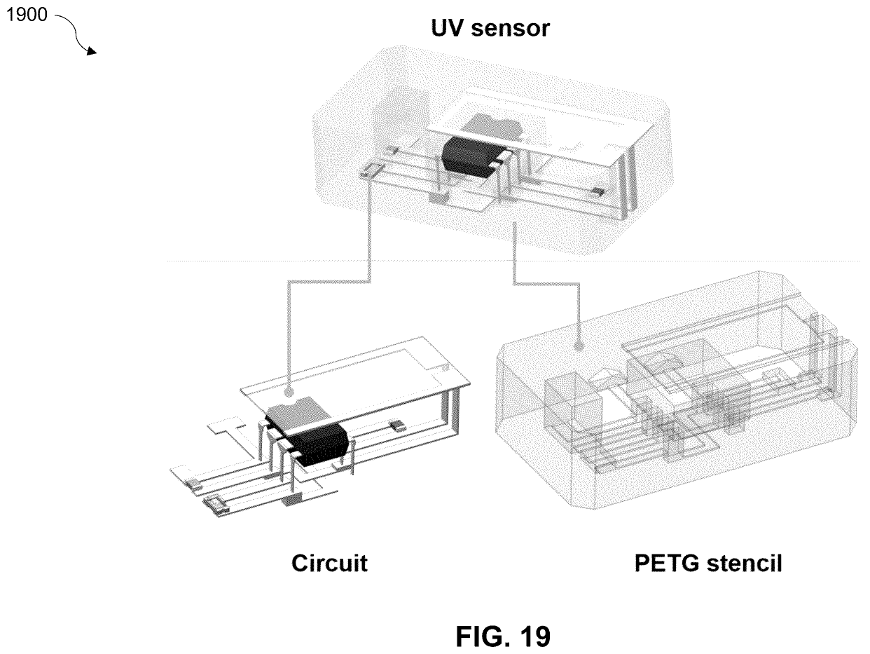

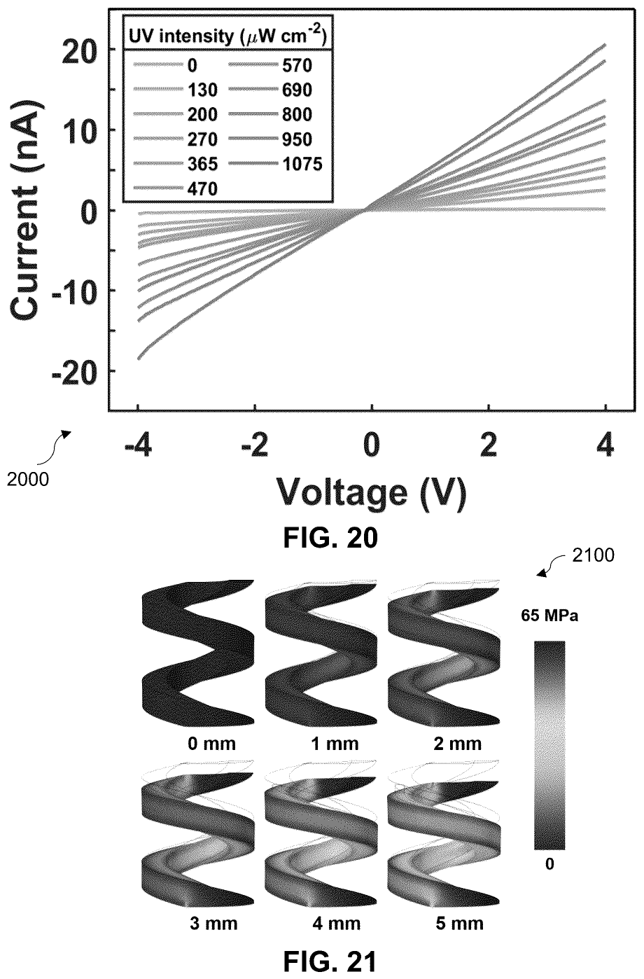

Further regarding FIG. 5A, conformable or flexible electronics fabrication are usually fabricated on planar substrates by lithography and then transferred to target substrates, resulting in devices confined to the outer surfaces. To demonstrate the capability of FMAP in fabricating functioning devices within 3D structures without lithography or transferring, a ZnO ultraviolet (UV) sensor, a LIG embedded strain-sensing spring, a close-looped haptic robotic manipulator, and a 3D electromagnet, are demonstrated in FIGS. 5A-5C. A UV sensor measures the environmental UV index. The fabrication begins with FFF printing of a 3D PETG stencil (see FIG. 19, described in more detail below), followed by DIW and FLI to fabricate Ag electrodes in the stencil. ZnO is used as the UV sensing material. Electrical components including a NE555 IC, a capacitor, a resistor, and a LED were integrated into the fabricated 3D circuit (see diagram 500 in FIG. 5A). When there is no UV stimulus, the resistance of ZnO is too large to be measured. When the UV light intensity increases from 130 μW/cm² to 1075 μW/cm², due to the generated charge carriers under the UV irradiation, the total resistance is dramatically reduced (see FIG. 20, described in more detail below). The corresponding photocurrents (I) at an applied bias of 3 V versus the UV light intensities (P) are plotted in plot 502 in FIG. 5A, from which their linear relationship in a log scale: ln(I)=0.98ln(P)−25.3 is derived with an R² value of 0.99. This high linearity suggests an accurate and robust sensing outcome. Then the designed circuit with a LED can indicate the UV intensity change. In this scenario, the IC (e.g., NE555 IC) acts as an oscillator to produce a square wave output. The fluctuating resistance of the UV sensor leads to a change in the frequency of the generated waveform, thereby affecting the blinking frequency of the LED. Theoretically, the “on” and “off” durations of the LED can be determined by tₒₙ=0.69×C×R₂ and t_{off}=0.69×C×(R₁+R₂). In this context, C and R₁ represent the values for a capacitor and a resistor, and R2 represents the resistance of ZnO. It shows that the on-off switching frequency is quite linear to the UV intensity at a relationship of f=3.9×10⁻³P+0.18 with an R² value of 0.99 (see plot 504 in FIG. 5A). The observation of the change of the frequency as the UV intensity increases.

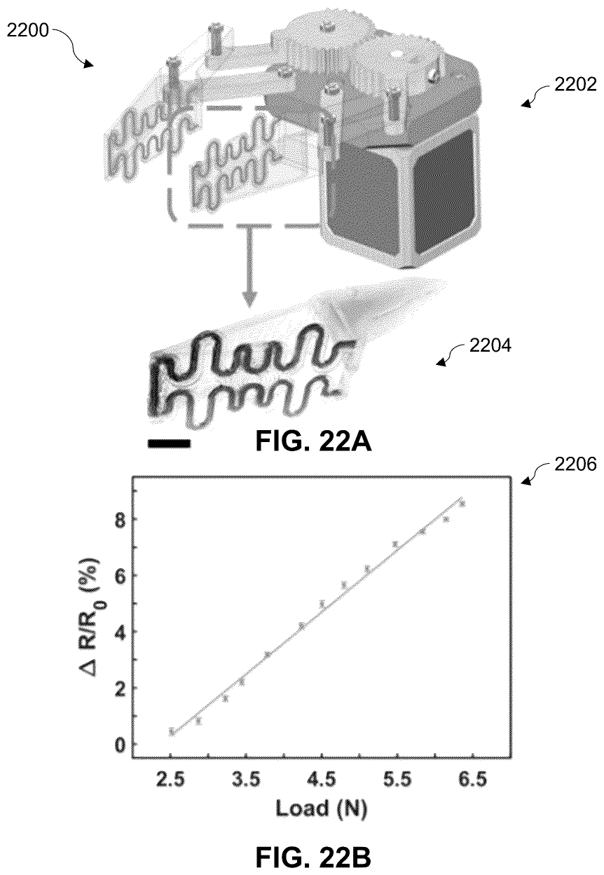

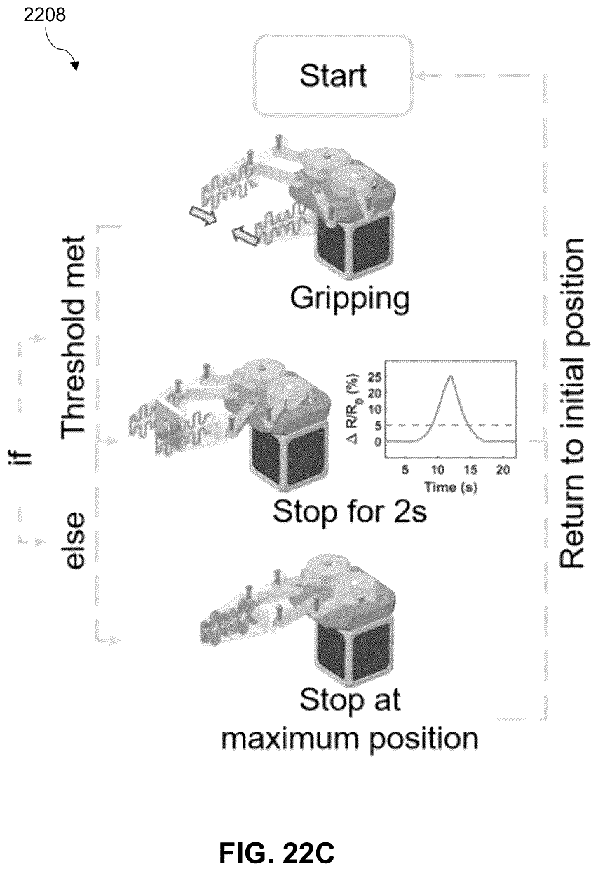

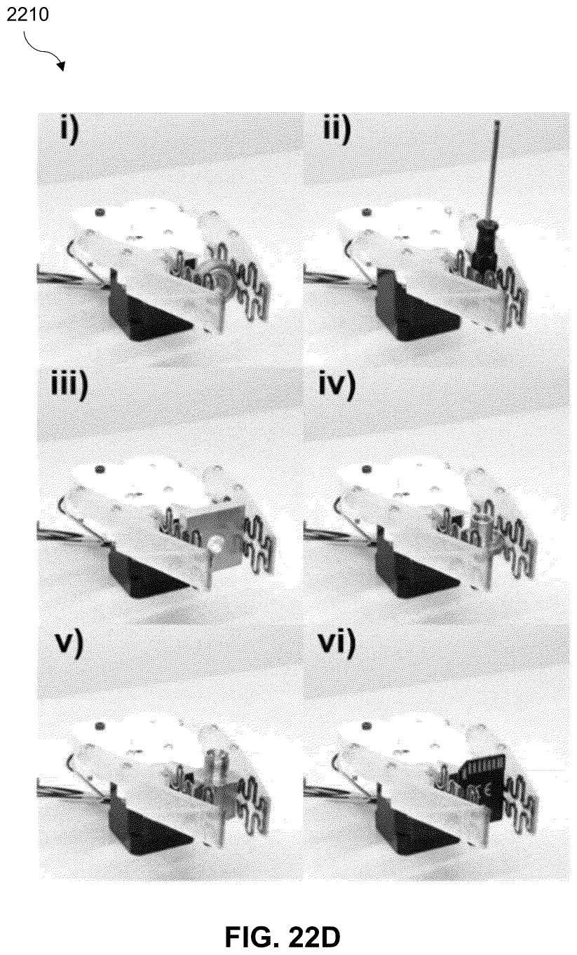

Further regarding FIG. 5B, a helical compression spring can be used for shock absorption and vibration isolation. To realize a close-loop control, monitoring the loading is necessary, which is traditionally done by attaching a displacement sensor to the spring's surface, but it tends to be inaccurate and quickly worn out. To tackle this issue, FMAP was deployed to print a functional spring from PC integrated with a LIG strain sensor (see diagram 506 in FIG. 5B). The process involves FFF of PC whose center of each layer (layer height: 0.12 mm) is integrated into LIG. As shown in plot 508 in FIG. 5B, the resistance change of the LIG (ΔR/R_{O}) is quite linear (R²=0.98) to the applied displacement (D), from which their relationship is determined to be: ΔR/R_{O}=2.6×10⁻³D−1.7×10⁻³. The finite element simulation (FEA) reveals the Von Mises stress distribution at different applied displacements to the spring (see FIG. 21, described in more detail below). Moreover, cycling testing, as shown in diagram 510 in FIG. 5B, by applying 3 mm displacement to the spring illustrates that the resistance change signals are consistent after 640 cycles, indicating high durability of the device (see plot 512 in FIG. 5B). To broaden its potential in a robotic application, a gripper made from PC with an embedded LIG strain sensor was fabricated by FMAP (see FIG. 22A, described in more detail below). This integrated gripper can sense force during manipulation, thus enhancing the robot's ability to grab a delicate object in a close-loop manner (see FIGS. 22B-22D, described in more detail below).

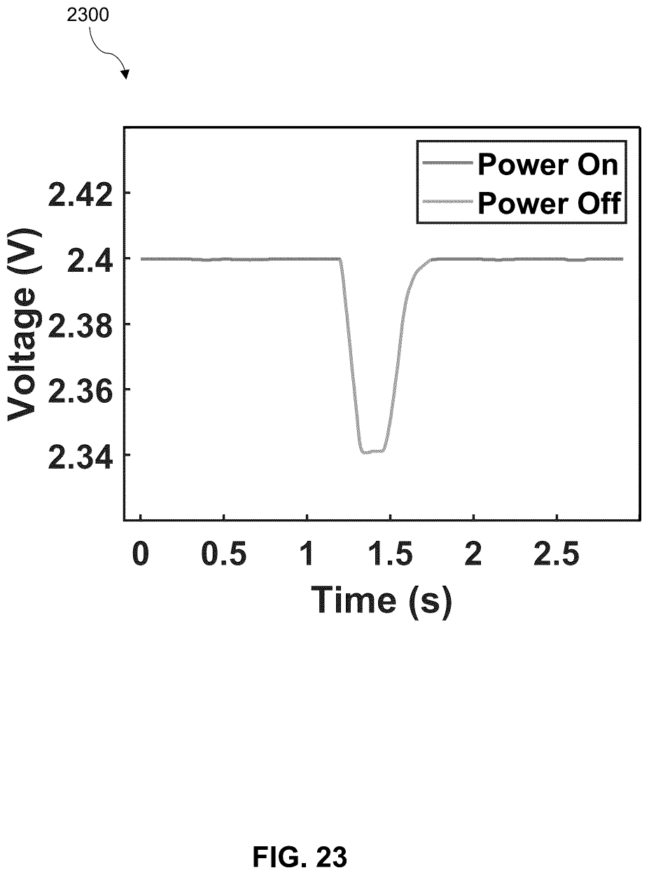

Further regarding FIG. 5C, an electromagnet is usually made of a coil where an electric current is passed for precise control of the magnetic field, thus is applied in an electrical motor, a magnetic resonance imaging machine, and a robot. When applied to a robot, the electromagnet can provide accurate and reliable feedback on the position and motion to realize a closed-loop control. FMAP was used to fabricate a micro electromagnet made from a laser-induced 4-layer Ag coil, and a laser-induced iron core in the middle of the coil, both of which are encapsulated by printed PETG (see diagram/photograph 514 in FIG. 5C). Although the Ag coil is placed vertically on four separate PETG layers, it is electrically connected, and the connection points are illustrated by blue dashed lines. The magnetic field of the electro-magnet is primarily determined by the current flowing through the coil, the number of turns in the coil, and the choice of core material. Increasing the current can create excessive Joule heat. Increasing the number of the coil turns increases the space. Thus, using the multi-layered coil as an inductor and the iron as the core material can well-satisfy the design constraints. The micro electromagnet is fabricated together with a rotating disk used for rotational speed measurement (see diagram/photograph 514 in FIG. 5C). When a continuous current passes the Ag coil, a magnetic field is generated, which can be sensed by a stationary Hall effect sensor when the electromagnet approaches. As shown in FIG. 23 (described in more detail below), when the coil is switched on, the voltage of the Hall sensor quickly decreases from 2.4 V to 2.34 V within 0.2 s and returns to 2.4 V within 0.5 s when the power is switched off. When the rotation speeds of the motor which carries the rotational disk increase from 20 revolutions per minute (rpm) to 200 rpm, the time interval between two consecutive voltage spikes—indication of time taken for a turn—is shortened from 2995 ms to 299 ms (see plot 516 in FIG. 5C). Correspondingly, the rotational speeds can be calculated from these time intervals. They agree well with the input rotational speeds with a R² of nearly 1.0 (see plot 518 in FIG. 5C), showing the high sensing fidelity. This success shows the potential for using FMAP to fabricate highly integrated magnetic devices in robotics with a closed-loop control scheme.

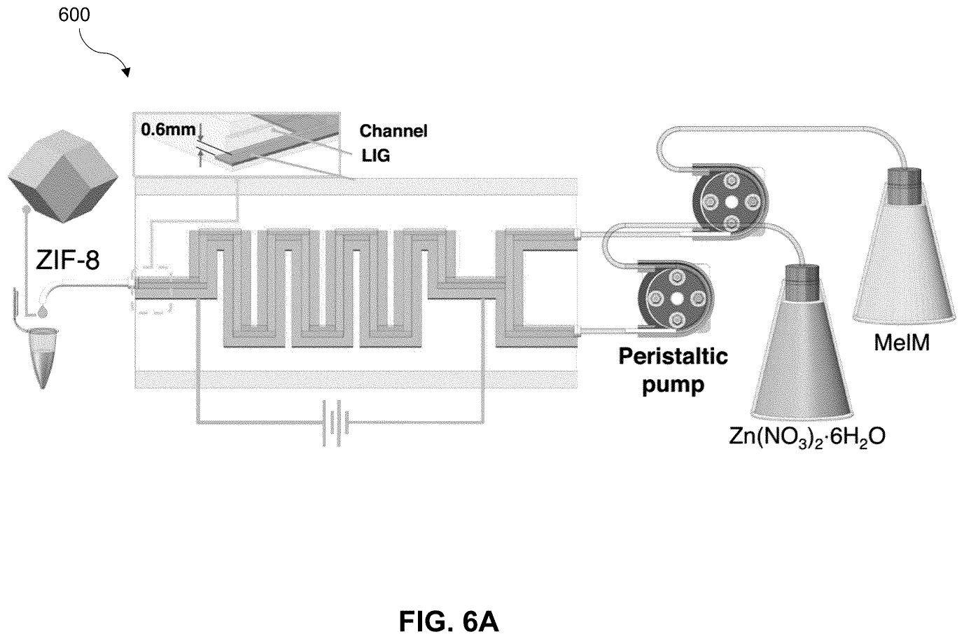

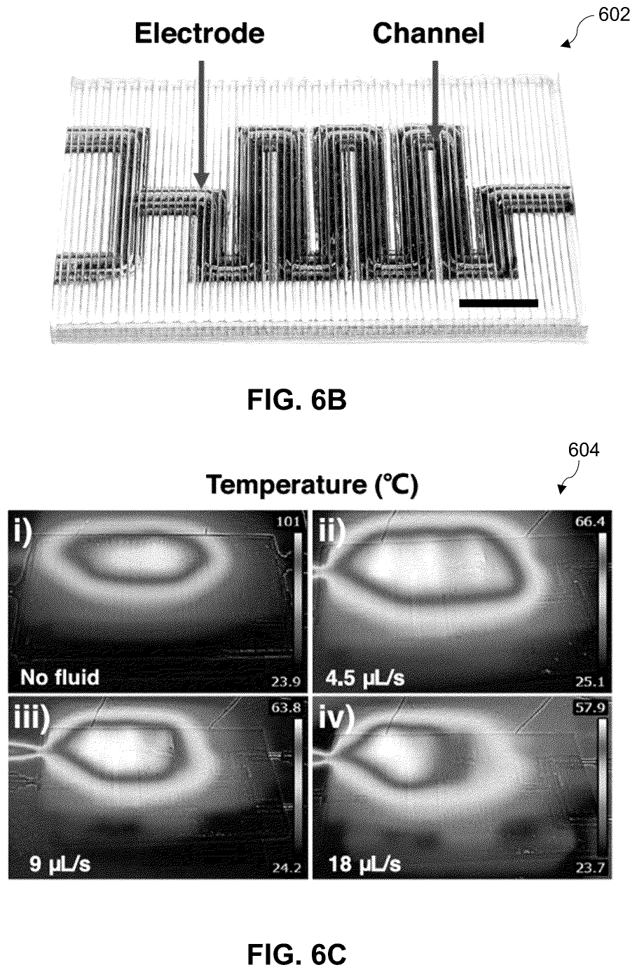

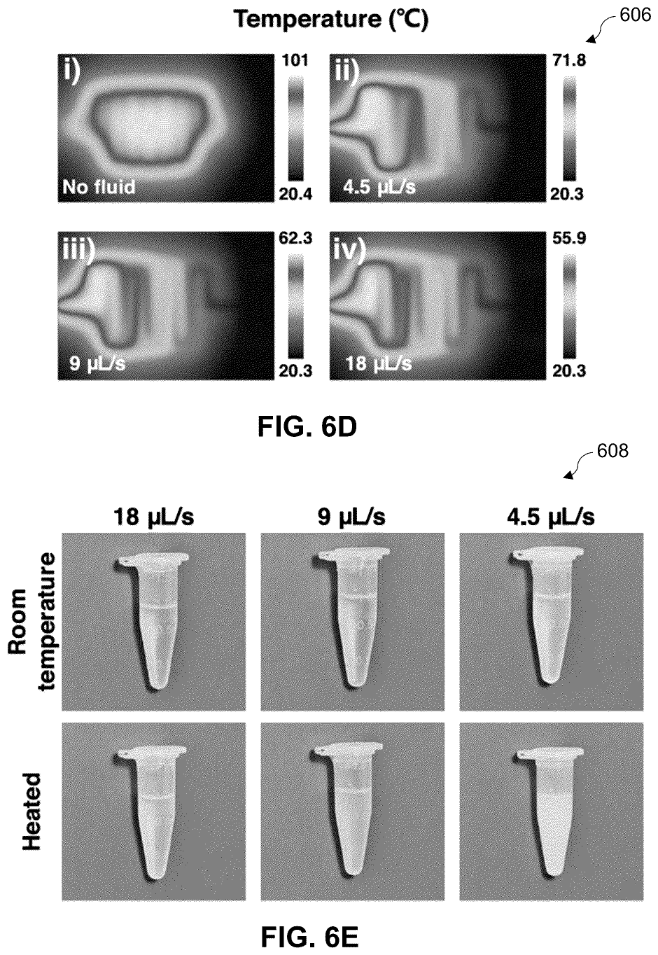

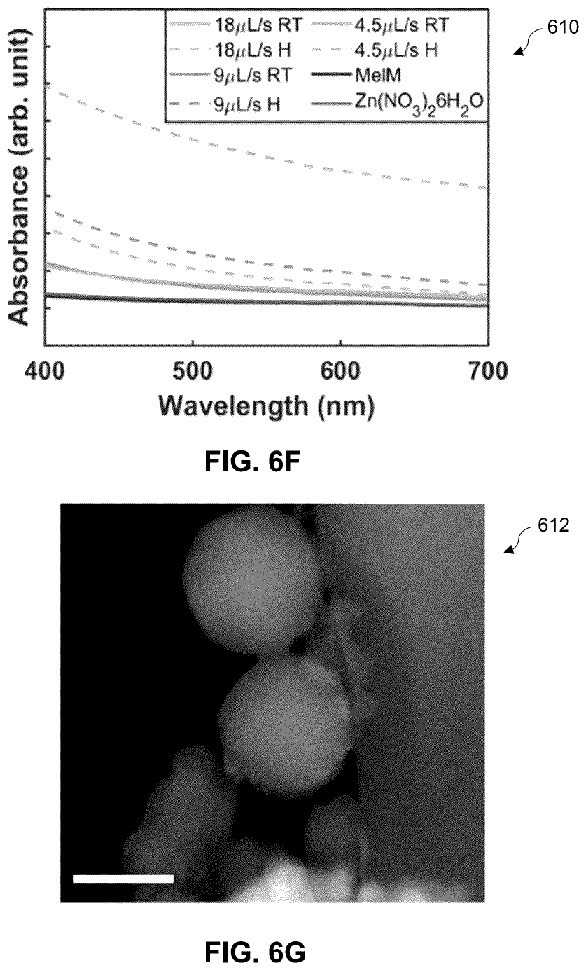

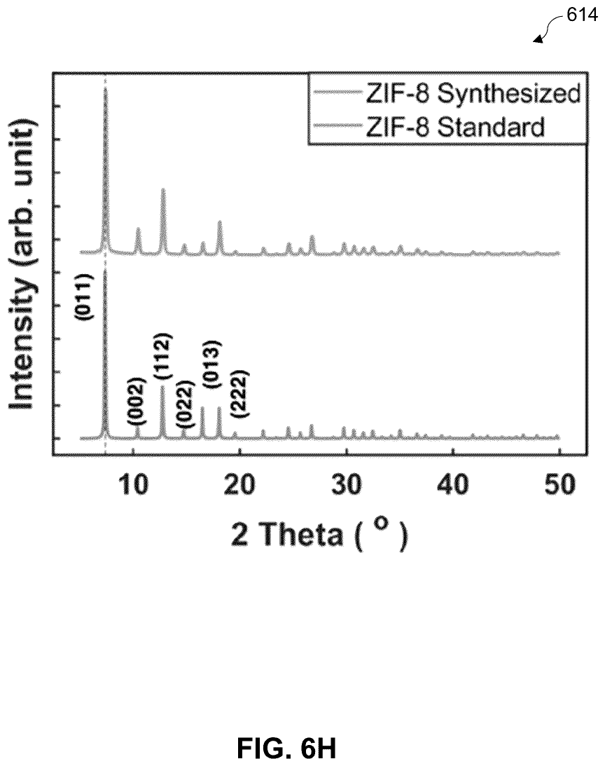

FIGS. 6A-6H illustrate a microfluidic flow reactor with an embedded LIG heater according to one embodiment of the present disclosure.

FIG. 6A illustrates diagram 600, a schematic of an assembled microfluidic flow reactor for ZIF synthesis. FIG. 6B is a photograph 602 of a fabricated reactor including an electrode and channels (e.g., microfluidic channels), where the scale bar represents 10 mm. FIG. 6C is a diagram 604 illustrating thermal images of the reactor taken at different flow rates when power is on. FIG. 6D is a diagram 606 illustrating FEA simulation on the temperature distribution of the channels at different flow rates. FIG. 6E is a collection of photographs 608 of samples synthesized at elevated temperatures and room temperature (“RT”). FIG. 6F is a plot 610 of UV-Vis spectra of samples synthesized under RT and Joule heating conditions. FIG. 6G is an image 612, namely a TEM image of synthesized ZIF-8 NPs by in-situ Joule heating at 4.5 μL/s, where the scale bar represents 200 nm. FIG. 6H is plot 614 illustrating an XRD spectrum of the synthesized ZIF-8 NPs by in-situ Joule heating at 4.5 μL/s and a standard ZIF-8 spectrum.

Further regarding FIGS. 6A-6H, microfluidic flow reactors can better control, with high efficiency, chemical reactions when compared to traditional bulk vessel reactors. For example, a 3D printed microfluidic reactor for synthesizing ZIF NPs with reduced reagent usage, fast reaction rate, and energy savings may be implemented. However, its operation is limited to room temperature, restricting the range of materials that can be synthesized. An embedded heating electrode for in-situ Joule heating could overcome this limitation. Demonstrated herein is the use of FMAP to one-step fabricate an integrated microfluidic reactor with a LIG electrode embedded 0.6 mm underneath the channels as a Joule heater (see FIGS. 6A, 6B). Two precursors for ZIF-8 synthesis were fed into the inlets of the channels which were heated by the LIG at a DC voltage of 30 V and a current of 0.1 A. The generated heat accelerates the reaction. To visualize the temperature distribution within the heated channels at various flowing rates (4.5, 9, and 18 μL/s), thermal images were captured using an IR camera (see FIG. 6C). When there is no liquid flowing through the channels, the temperature can reach 101° C. In contrast, as the flow rate increases from 4.5 μL/s to 18 μL/s, the temperature gradually decreased from 66.4° C. to 57.9° C. because heat is carried away by the flowing liquid. The FEA simulation shows the same trend that a higher flow rate leads to the lower temperatures (see FIG. 6D). As a comparison, the reactions with the flow rates of 4.5 μL/s, 9 μL/s, and 18 μL/s were conducted at room temperature (RT). The samples collected from the reactions at room temperature and elevated temperatures exhibit obvious appearance differences; the former set are transparent while the later set are translucent (see FIG. 6E). It may suggest success of the synthesis by the Joule heating. This hypothesis is confirmed by UV-vis absorbance results (see FIG. 6F). The samples synthesized at elevated temperatures exhibit much higher absorbance than the samples synthesized at RT, which show no difference with the baseline curves of the precursors. The morphologies and crystal structures of the as-synthesized ZIF-8 NPs were further examined by Transmission Electron Microscopy (TEM), and X-ray diffraction (XRD). The TEM image in FIG. 6G shows that the ZIF-8 NPs are decagonal; this is one possible projected view of display a particle with a rhombic dodecahedron morphology. The NPs have a diameter of ˜200 nm. The XRD pattern exhibits characteristic peaks at 2θ of 7.2°, 10.2°, 12.6°, 14.6°, 16.3°, and 17.9°, corresponding to the (011), (002), (112), (022), (013), and (222) planes of ZIF-8 (see FIG. 6H). The sharp and intense peaks indicate a high crystallinity of ZIF-8 synthesized with the in-situ Joule heating. These findings highlight the efficiency and control afforded by the microfluidic reactor and its in-situ heating capability.

FIGS. 7A-7C illustrate a workflow of fabricating a wireless LED using FMAP according to one embodiment of the present disclosure.

FIG. 7A illustrates diagram 700 for design and modeling of electrodes for a wireless LED and respective G-code generation. The coil and shell electrodes are modeled independently. Subsequently, the toolpaths for both the coil and shell are generated using a slicer tool, which are tailored to the specific requirements of FFF, DIW, and FLI.

FIG. 7B illustrates diagram 702 for toolpaths for FFF, DIW, and FLI. To achieve precise positioning of the three end effectors, the toolpaths are integrated with their respective offset parameters. To this end, computing device 106 may be programmed and configured to execute a modular control scheme enabling coordinated toolpath generation for FFF, DIW, and FLI within a single instruction set. For example, a modular control scheme may provide a flexible, component-based architecture where different processes (e.g., FFF, DIW, FLI) are treated as independent but interoperable modules. Each process may be handled by a separate module or subsystem, each with its own control logic and/or control parameters. Coordinated or unified toolpath generation accounts for all three processes in a synchronized way so the transitions between them are seamless and efficient. A single instruction set may be implemented and configured to compile a single, integrated set of instructions (e.g., G-code or a higher-level abstraction) to control a given (e.g., entire) fabrication sequence. Such a modular control scheme and single instruction set is beneficial multi-material and/or hybrid manufacturing as described herein, and provides real-time adaptability, where one process can adjust based on feedback from another. Additional benefits may include simplified programming (e.g., reduced need to manually coordinate each step). For example, instead of running three separate programs for FFF, DIW, and FLI, a modular control scheme may be configured to generate a single cohesive instruction set that instructs the machine (e.g., platform 100) when and how to switch between tasks, and align toolpaths and/or timing for optimal results. Dedicated controllers may be implemented as part of platform 100 and/or computing device 106 to manage multiple process modules (e.g., for FFF, DIW, FLI, where each process may be implemented via a dedicated software module with defined inputs/outputs and/or control logic/control parameters. As part of this, a unified toolpath generator may be configured to create a composite toolpath that includes all three processes in a single spatial and/or temporal sequence, such as via a custom instruction set (e.g., single instruction set). Before execution, computing system 106 may be configured to simulate the entire sequence to check for potential issues such as timing conflicts, etc. Hardware components of platform 100 and/or computing device 106 may also be configured in a corresponding designated modular manner and synchronized. This may further include the use of a gantry such as a multi-head gantry and/or one or more robotic arms to assist, for example, with switching between processes. The modular control scheme may include sensor feedback loops for the sensors as described herein for real-time data back to the controller. enabling adaptive/dynamic control as described herein.

FIG. 7C illustrates time-lapse images 704-708 of the different fabrication steps for a wireless LED: image 704 (e.g., at i) in FIG. 7C) shows printing of a polycarbonate (PC) substrate; image 706 (e.g., at ii) in FIG. 7C) shows multilayer LIG/Ag electrodes are fabricated within the printed PC structure; and image 708 (e.g., at iii) in FIG. 7C) shows conformal patterning of the LIG/Ag electrodes on the surface of the PC structure. Throughout this procedure, all actuators work synergistically to ensure that the laser beam remains perpendicular to the target 3D surface. The various actuators and other hardware components of platform 100 may be in operative communication with one or more dedicated controllers and/or other processors, memories, etc., to enable communication with and/or control by external computing devices such as computing device 106.

FIG. 8 illustrates a diagram 800 of a workflow of using FMAP to fabricate a 3D wireless LED with LIG/Ag electrodes made from TPU and a precursor mixture, which includes lignin and silver citrate according to one embodiment of the present disclosure. Including lignin in the silver citrate ink can benefit laser induction for LIG formation from polymers such as TPU and PETG which are not carbonized by laser directly.

FIGS. 9A and 9B illustrate characterization on the LIG induced from PC printed with different layer heights according to one embodiment of the present disclosure. FIG. 9A illustrates cross-sectional optical images 900 of the LIG induced from PC printed with five different layer heights, a scan rate of 300 mm/min and power of 2.5 W, where the scale bar represents 200 μm. FIG. 9B illustrates plot 902 showing a change of the resistance of LIG in the z-axis direction vs. the layer height, where the error bars indicate the standard deviation obtained from more than 5 sheet resistance measurements. Note: because of decreased conductivity along the z-axis as the increased layer height, a layer height of 0.15 is typically employed for all the showcased devices in the experiments and/or results described herein.

FIG. 10 illustrates plot 1000 showing sheet resistance of LIG as a function of laser scan rate according to one embodiment of the present disclosure.

FIGS. 11A and 11B illustrate a relationship between laser power and the LIG thickness according to one embodiment of the present disclosure. FIG. 11A illustrates photograph 1100 showing cross sections of 8 LIG samples made by different laser powers of 1, 1.5, 2, 2.5, 3, 3.5, 4, and 4.5 W. FIG. 11B illustrates plot 1102 showing LIG thickness as a function of laser power. The scale bar represents 500 μm.

FIG. 12A-12D illustrate the resolution of laser induction on various substrates according to one embodiment of the present disclosure. FIG. 12A illustrates a photograph 1200 showing a LIG strip with 218 μm linewidth induced from lignin on a PETG substrate. FIG. 12B illustrates a photograph 1202 showing a LIG strip with 235 μm linewidth induced from a PVDF substrate. FIG. 12C illustrates a photograph 1204 showing a LIG and Ag strip with 247 μm linewidth induced from the PC and Ag precursor. FIG. 12D illustrates a photograph 1206 showing a 104 μm-width laser induced Ag on PC. The scale bar in FIGS. 12A-12D represents 200 μm.

FIGS. 13A-13C illustrate tensile testing conducted on PC samples featuring different dimensions of embedded LIG according to one embodiment of the present disclosure. FIG. 13A illustrates diagram 1300 showing a schematic that illustrates the structure of a tensile testing specimen with LIG embedded inside. FIG. 13B illustrates plot 1302 showing stress-strain curves of PC specimens with varied thicknessed LIG. FIG. 13C illustrates plot 1304 showing stress-strain curves of PC specimens with varied width LIG.

FIG. 14 illustrates a plot 1400 showing Raman spectra of LIG from PC induced with different laser powers according to one embodiment of the present disclosure.

FIGS. 15A-15F illustrate various 3D structures with embedded LIG patterns fabricated by FMAP according to one embodiment of the present disclosure. FIG. 15A illustrates letters such as in the form of an “MU” logo 1500 made from LIG embedded in a printed PVDF structure. FIG. 15B illustrates an airfoil 1502 embedded with a LIG Zigzag pattern in PC. FIG. 15C illustrates an LIG lattice 1504 structure embedded in a PC cuboid. FIG. 15D illustrates a printed PC gear 1506 embedded with LIG. FIG. 15E illustrates a schwarz diamond surface 1508 in PC. FIG. 15F illustrates a 3D LIG fan 1510 embedded in PC. The scale bar in FIGS. 15A-15F represents 10 mm.

FIGS. 16A and 16B illustrate a spatially patterned LIG ‘MU’ logo fabricated by FMAP according to one embodiment of the present disclosure. FIG. 16A illustrates a diagram 1600 showing a workflow of fabricating the 3D ‘MU’ logo. FIG. 16B illustrates a diagram/photograph 1602 showing a scheme and a photograph showing the structure of the fabricated 3D ‘MU’ logo. The scale bar in FIGS. 16A and 16B represents 10 mm.

FIGS. 17A and 17B illustrate photographs showing fabrication steps for the crossbar LED array by FMAP according to one embodiment of the present disclosure. More specifically, FIG. 17A illustrates photographs 1700 showing fabrication steps for a crossbar LED array by FMAP, where the scale bar represents 10 mm. FIG. 17B illustrates photographs 1702 showing fabrication steps for another embodiment of a crossbar LED array by FMAP where the scale bar represents 5 mm.

FIGS. 18A and 18B illustrate capacitance changes as a function of length of electrodes (see plot 1800 in FIG. 18A) and thickness of the insulator in between the two electrodes (see plot 1802 in FIG. 18B), according to one embodiment of the present disclosure. The data indicate trends consistent with the capacitance calculation, where capacitance is positively proportional to the electrode length while inversely proportional to the distance between electrodes. Repeated measurements were taken from the same samples for standard deviation calculation.

The experimental outcomes well agree with the capacitance formula,

$$C = \frac{{∈}_{0} A}{d} ,$$

where A represents the electrode overlap area and d signifies the distance between the electrodes. As illustrated in FIGS. 18A and 18B, it is evident that the variation in capacitance is directly proportional to the electrode area and inversely proportional to the electrode separation distance.

FIG. 19 illustrates diagram 1900 showing a schematic showing the circuits and electrical components for a UV sensor according to one embodiment of the present disclosure. The PETG stencil for the Ag electrodes is also illustrated.

FIG. 20 illustrates plot 2000 showing I-V curves of the UV sensor at varying UV light intensities ranging from 0 to 1075 μW/cm² according to one embodiment of the present disclosure. Among these I-V (current-voltage) curves, the linear behavior can be ascribed to the Ohmic connection between the ZnO material and the Ag electrode. To illustrate, at an incident power (P) of 130 μW/cm², the I-V curve exhibits a slope of 5.38e⁻¹⁰. As the incident power increase, the slope proportionally increases, reaching 4.67e⁻⁹ at P=1075 μW/cm². This experimental observation can be attributed to the diminishing resistance from the creation of charge carriers induced by UV.

FIG. 21 illustrates diagram 2100 showing Von Mises stress distribution of the spring under displacements of 0-5 mm derived from FEA simulation according to one embodiment of the present disclosure.

FIGS. 22A-22D illustrate performance of a fabricated gripper with an embedded LIG strain sensor according to one embodiment of the present disclosure. FIG. 22A illustrates a diagram/photograph 2200 showing a schematic 2202 showing an assembled manipulator and a photograph 2204 showing a strain sensor embedded gripper fabricated by FMAP. FIG. 22B illustrates a plot 2206 showing resistance change as a function of load. FIG. 22C illustrates a diagram 2208 showing a scheme showing a workflow of a feedback loop control. FIG. 22D illustrates photographs 2210 showing the manipulator adeptly manipulating: (i) a ball bearing; (ii) a screwdriver; (iii) an aluminum block; (iv) a t-nut; (v) a brass adapter; and (vi) an SD card. The scale bar for FIGS. 22A-22D represents 10 mm.

In response to varying gripping forces while manipulating objects, the LIG strain sensor undergoes corresponding deformations, generating distinct electrical signals. This behavior is illustrated in FIG. 22B, which displays the linear response of the strain sensor as the applied load changes within the range of 2.5N to 6.5N. Accordingly, a force feedback control algorithm was developed. It halts the gripper once the electrical strain attains a threshold of 5%, as shown in FIG. 22C. Implementing this control scheme empowers the gripper to adeptly grip a range of objects, including bearings, screwdrivers, aluminum blocks, T-nuts, brass adapters, and SD cards (FIG. 22D).

FIG. 23 illustrates plot 2300 showing voltage response of a Hall sensor as an approached micro electromagnet is switched “on” and “off” according to one embodiment of the present disclosure.

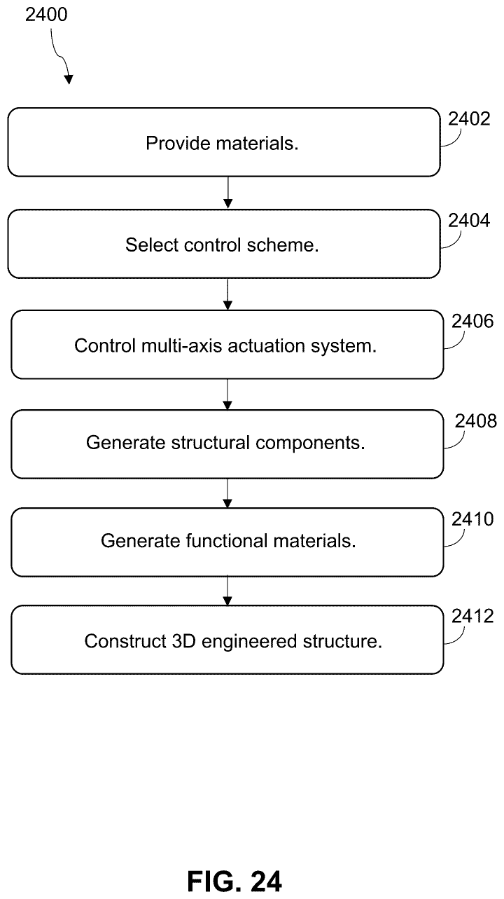

FIG. 24 is a flow diagram of an example method 2400 according to one embodiment of the disclosure. Method 2400 includes providing 2402 materials for constructing 3D engineered structures, such as the materials described herein. This may include PC, lignin, etc. Method 2400 includes selecting 2404 a control scheme such as described herein (e.g., a modular control scheme). Aspects of the control scheme may include defining component control, such as setting a laser power as described herein. Method 2400 includes controlling 2406 the multi-axis actuation system (e.g., controlling FMAP platform 100 shown in FIG. 1A, and more specifically a 5-axis FMAP platform 100). This may include 5-axis control as described herein, as well as other control via other control schemes such as the dynamic sensor-based control as described herein. Method 2400 includes generating 2408 structural components as described herein, such as shown in FIG. 1C. Method 2400 includes generating 2410 functional materials, such as shown in FIG. 1C. Method 2400 includes constructing 2412 3D engineered structures as described herein, e.g., via FMAP.

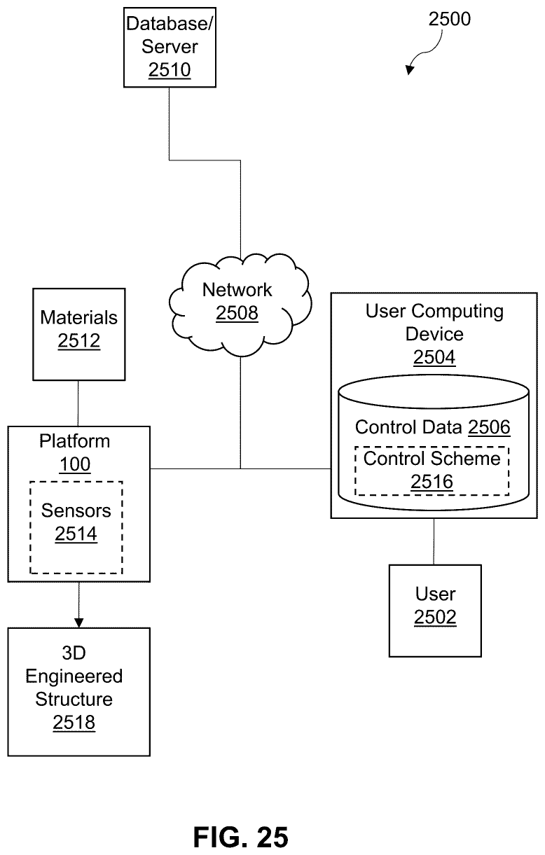

FIG. 25 is a block diagram schematically illustrating an overall configuration 2500 of an FMAP platform (e.g., platform 100 shown in FIG. 1A, also referred to as a multi-axis actuation system) and associated computing system (e.g., 106) and in accordance with one aspect of the disclosure. FIG. 25 illustrates a simplified block diagram of a computing system such as computing system 106 shown in FIG. 1A, and operated by a user 2502, where computing system 106 may be implemented and/or configured as a user computing device 2504 for implementing the fabrication as described herein. As illustrated in FIG. 25, user computing device 2504 may be configured to implement at least a portion or even all or most of the tasks associated with the disclosed methods and/or other techniques using the disclosed components described herein. User computing device 2504 may include memory storing control data 2506 for executing control (e.g., software control) of platform 100, and be connected via a network 2508 to additional computing devices such as a database/server 2510. In some embodiments, data such as control data 2506 may additionally or alternatively be stored at and retrieved from database/server 2510. As shown in FIG. 25, materials 2512 such as those described herein are provided for use with platform 100. Platform 100, including sensors 2514 such as the sensors described herein, and being controlled by control data 2506, such as via a control scheme 2516 as described herein, may then construct 3D engineered structures 2518 as described herein. Control data 2506 may provide software control for FMAP as described herein. Control data 2506 may be implemented via dedicated hardware such as dedicated processors, controllers, etc., and/or in conjunction with other control software and/or control routines as described herein. Control data 2506 may include programs, algorithms, models, scripts, routines, and the like, and may have interoperability with the hardware of platform 100, such as any motors, fans, etc. of platform 100 as described herein. Thus, control data 2506, and specifically a control scheme 2516 such as a modular control scheme as described herein, is/are uniquely configured, along with any associated processors, controllers, etc., to carry out FMAP itself and/or any processes included within FMAP, as described herein, and to realize the unique controls needed for integrating FFF, DIW, and FLI as described herein.

User computing device 2504 may be utilized by user 2502 to conduct/view/analyze results of the various tests and/or experiments described herein and/or control operation of platform 100 and its various components, fabrication via platform 100, etc. User computing device 2504 may be utilized by user 2502 to create, modify, and/or implement device design/fabrication plans, as well as execute the generation and/or construction of devices or parts of devices according to such design/fabrication plans. User computing device 2504 may be utilized by user 2502 to modify control schemes/routines, including all aspects of control for components such as end effectors 112, including associated motion and/or rotation thereof, as well as to control delivery/distribution/utilization of materials described herein via end effectors 112 (e.g., to control any providing/distribution/application of filaments, inks, laser pulses, etc.), and fabrication using such materials.

Network 2508 may be any network that allows local area or wide area communication between the devices. For example, network 2508 may allow communicative coupling to the Internet through at least one of many interfaces including, but not limited to, at least one of a network, such as the Internet, a local area network (LAN), a wide area network (WAN), an integrated services digital network (ISDN), a dial-up-connection, a digital subscriber line (DSL), a cellular phone connection, and a cable modem. User computing device 2504 may be any device capable of accessing the Internet including, but not limited to, a desktop computer, a laptop computer, a personal digital assistant (PDA), a cellular phone, a smartphone, a tablet, a phablet, wearable electronics, smart watch, or other web-based connectable equipment or mobile devices.

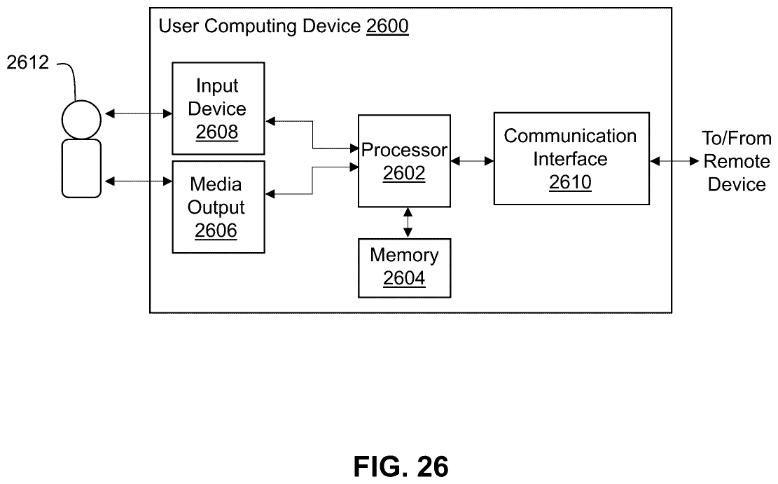

FIG. 26 depicts a component configuration of a computing device 2600 such as computer system 106 and/or user computing device 2504. In some aspects, computing device 2600 may be the same as or similar to computer system 106 and/or user computing device 2504. Computing device 2600 includes one or more processors 2602, one or more memories 2604, a media output component 2606 (e.g., speaker, display, etc.), and input device 2608 (e.g., mouse, keyboard, touch input, etc.), and a communication interface 2610 (e.g., for communicating with other computing devices such as database/server 2510 and/or a controller of platform 100). A user 2612 (e.g., the same as or similar to user 2502) may access components of computing device 2600. For example, user 2612 may be a technician running a test using platform 100 shown in FIG. 1A.

Computing device 2600 may include processor 2602 for executing computer-readable/-executable instructions. In some aspects, executable instructions may be stored in a memory area of memory 2604. Processor 2602 may include one or more processing units (e.g., in a multi-core and/or parallel configuration), and/or a dedicated controller as described herein. Memory 2604 may be any device allowing information such as executable instructions and/or other data to be stored and retrieved. Memory 804 may include one or more non-transitory computer-readable media (e.g., hard drive, RAM, ROM, and the like). The individual components of platform 100, such as in association with actuators, pumps, and the like, may include a similar configuration as shown in FIG. 25, and include respective processors (e.g., controllers), memories, interfaces, etc., as described herein, such as for communication with and/or control by external devices such as computing device 106, user computing device 504, and/or computing device 2600.

Computing device 2600 may also include at least one media output component 2606 for presenting information to user 2612. Media output component 2606 may be any component capable of conveying information to user 2612. In some aspects, media output component 2606 may include an output adapter, such as a video adapter and/or an audio adapter. An output adapter may be operatively coupled to processor 2602 and operatively coupled to an output device such as a display device (e.g., a liquid crystal display (LCD), organic light emitting diode (OLED) display, cathode ray tube (CRT), or “electronic ink” display) or an audio output device (e.g., a speaker or headphones). In some aspects, media output component 2606 may be configured to present an interactive user interface (e.g., a web browser or client application) to user 2612.

In some aspects, computing device 2600 may include input device 2608 for receiving input from user 2612. Input device 2608 may include, for example, a keyboard, a pointing device, a mouse, a stylus, a touch sensitive panel (e.g., a touch pad or a touch screen), a camera, a gyroscope, an accelerometer, a position detector, and/or an audio input device. A single component such as a touch screen may function as both an output device of media output component 2606 and input device 2608.

Computing device 2600 may also include communication interface 2610, which may be communicatively coupled to a remote device or a data center. Communication interface 2610 may include, for example, a wired or wireless network adapter or a wireless data transceiver for use with a mobile phone network (e.g., Global System for Mobile communications (GSM), 3G, 4G or Bluetooth) or other mobile data network (e.g., Worldwide Interoperability for Microwave Access (WIMAX)).

Stored in memory 2604 are, for example, computer-readable/-executable instructions for providing a user interface to user 2612 via media output component 2606 and, optionally, receiving and processing input from input device 2608. A user interface may include, among other possibilities, a web browser and client application. Web browsers enable users 2612 to display and interact with media and other information typically embedded on a web page or a website from a web server. A client application allows users 2612 to interact with a server application associated with, for example, a vendor or business.

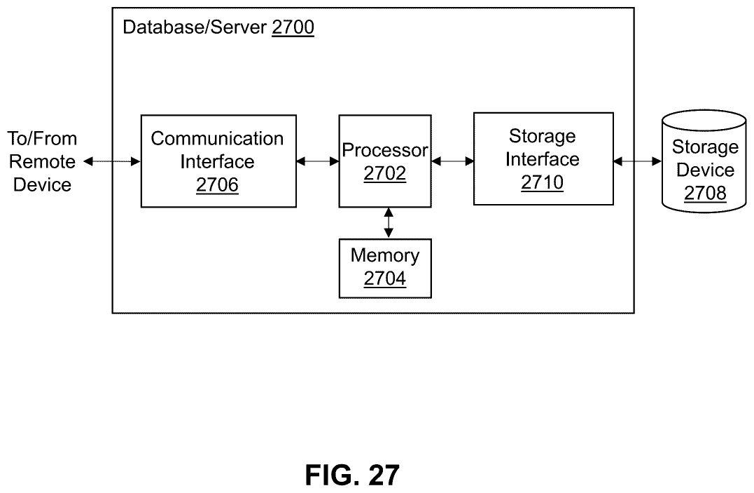

FIG. 27 illustrates an example configuration of a database/server system 2700. Database/server system 2700 may include, but is not limited to, database/server 2510 shown in FIG. 25. Database/server 2700 may include a processor 2702 for executing instructions. Instructions may be stored in a memory area of memory 2704, for example. Processor 2702 may include one or more processing units (e.g., in a multi-core or parallel configuration).

Processor 2702 may be operatively coupled to a communication interface 2706 such that database/server 2700 may be capable of communicating with a remote device such as user computing device 2504 (shown in FIG. 25) or one or more other computer or server systems. For example, communication interface 2706 may receive requests from user computing device 2504 via a network 2508 (shown in FIG. 25).

Processor 2702 may also be operatively coupled to a storage device 2708. Storage device 2708 may be any computer-operated hardware suitable for storing and/or retrieving data. In some aspects, storage device 2708 may be integrated in database/server 2700. For example, database/server 2700 may include one or more hard disk drives as storage device 2708. In other aspects, storage device 2708 may be external to database/server 2700 and may be accessed by a plurality of databases/servers 2700. For example, storage device 2708 may include multiple storage units such as hard disks or solid state disks in a redundant array of inexpensive disks (RAID) configuration. Storage device 2708 may include a storage area network (SAN) and/or a network attached storage (NAS) system.

In some aspects, processor 2702 may be operatively coupled to storage device 2708 via a storage interface 2710. Storage interface 2710 may be any component capable of providing processor 2702 with access to storage device 2708. Storage interface 2710 may include, for example, an Advanced Technology Attachment (ATA) adapter, a Serial ATA (SATA) adapter, a Small Computer System Interface (SCSI) adapter, a RAID controller, a SAN adapter, a network adapter, and/or any component providing processor 2702 with access to storage device 2708.

Memory 2604 (shown in FIG. 26) and memory 2704 may include, but are not limited to, non-transitory random access memory (RAM) such as dynamic RAM (DRAM) or static RAM (SRAM), read-only memory (ROM), erasable programmable read-only memory (EPROM), electrically erasable programmable read-only memory (EEPROM), and non-volatile RAM (NVRAM). The above memory types are example only, and are thus not limiting as to the types of memory usable for storage of a computer program.

### Additional Embodiments and/or Aspects

Described below are one or more additional aspects and/or one or more additional embodiments contemplated by the present disclosure that are able to be integrated and/or implemented as described herein.

One or more additional aspects include a (e.g., fabrication) system and/or method as described herein where one or more target 3D engineered structures includes: (1) a crossbar circuit for a light emitting diode (LED) display; (2) an ultraviolet (UV) sensor including zinc oxide and laser-induced conductive traces; (3) a capacitive touchpad including a plurality of electrodes formed from laser-induced graphene or LIG/Ag composites; (4) a strain sensor integrated into a spring structure, wherein the strain sensor includes laser-induced graphene aligned along the spring axis; (5) a micro electromagnet including a laser-induced silver coil and a magnetic core formed by laser-induced iron; and/or (6) a microfluidic reactor with a Joule heating element formed by embedded laser-induced graphene. The crossbar circuit for the LED display aspect may include fabricating bottom and top electrode layers using FLI, encapsulating them using FFF, and depositing interconnects via DIW. The spring structure aspect may include embedding a laser-induced graphene trace within a 3D printed spring structure by alternating FFF deposition and FLI processing, such that the electrical resistance changes under mechanical displacement. The microfluidic reactor aspect may include embedding a Joule heating element beneath microfluidic channels by inducing laser-induced graphene from a thermoplastic substrate.

One or more additional aspects include a (e.g., fabrication) system and/or method as described herein where the functional materials include a composite of laser-induced graphene and silver, formed by depositing a silver precursor onto a graphene trace and processing it using laser induction.

One or more additional aspects include a (e.g., fabrication) system and/or method as described herein where a conductive trace formed via the freeform laser induction process exhibits a sheet resistance less than 15 ohms per square.

One or more additional aspects include a (e.g., fabrication) system and/or method as described herein where a laser-induced trace width of the functional material is approximately 100 micrometers or less.

One or more additional aspects include a (e.g., fabrication) system and/or method as described herein where the multi-axis actuation system includes six or more degrees of freedom implemented via robotic arms and/or gantry mechanisms.

One or more additional aspects include a (e.g., fabrication) system and/or method as described herein where including a plurality of extruders for fused filament fabrication and/or a plurality of nozzles for direct ink writing to support multi-material printing.

One or more additional aspects include a (e.g., fabrication) system and/or method as described herein where a computing device is configured to dynamically orient the laser module to maintain normal incidence on curved or non-planar surfaces during the laser induction process.

One or more additional aspects include a (e.g., fabrication) system and/or method as described herein where a computing device is configured to dynamically adjust the orientation of the laser module relative to a curved or non-planar surface of the structural components to maintain optimal laser focus during freeform laser induction.

One or more additional aspects include a (e.g., fabrication) system and/or method as described herein where a fused filament fabrication process includes simultaneous or sequential deposition of two or more thermoplastic materials to create mechanically or optically differentiated regions.

One or more additional aspects include a (e.g., fabrication) system and/or method as described herein where a computing device executes a modular control scheme enabling coordinated toolpath generation for fused filament fabrication, direct ink writing, and freeform laser induction within a single instruction set.

One or more additional aspects include a (e.g., fabrication) system and/or method as described herein where one or more sensors are configured to provide real-time feedback to the computing device for adjusting process parameters during fabrication.

One or more additional aspects include a (e.g., fabrication) system and/or method as described herein where one or more target 3D engineered structures includes a wearable electronic device fabricated with flexible substrates and embedded functional traces.

### Discussion

Discussed below are non-limiting examples of various tests and/or experiments that use, and/or applications and/or implementations of, the systems, methods, and/or techniques described herein, including various aspects of the tests, experiments, applications and/or implementations. As described herein, FMAP enables the fabrication and assembly of diverse functional and structural materials into a 3D engineered object. The functional materials may encompass laser-processable materials like LIG, metals, and metal oxides. As a concept of demonstration, various applications including crossbar LED circuits, capacitive sensor-based touchpads and sliders for HMI, and a UV sensor, are fabricated and tested. Moreover, a LIG strain sensor-embedded spring, gripper for haptic grasping, and micro 3D electromagnets, were realized. Further expanding the application area, a microfluidic reactor featuring Joule heating was demonstrated. The sensors within these prints consistently exhibit attributes of high linearity, accuracy, and rapid response. Overall, FMAP offers advantages for programmed assembly of both functional and structural materials into 3D engineered objects.

Despite the enormous potential for FMAP as described herein in 3D electronic manufacturing, there are improvements, contemplated herein, that may be made in the FMAP. For example, processing rate may be improved. Other embodiments of may include FLI, DIW, and FFF processes configured to be operated separately. To enhance efficiency, end-effectors of these processes can be equipped on different robotic manipulators to perform simultaneous, collaborative work. A second improvement relates to the lasers that are used for fabrication. Although the current implemented laser can achieve ˜100 μm linewidth meeting the requirement for most printed wearable electronics, higher resolution can be attained by upgrading the laser system, e.g., using a laser with smaller laser spots. Last but not least, while this disclosure focuses largely on functional materials for electronic applications, FMAP may be extended to different applications such as robotic manipulation, and/or incorporating other processes such as aerosol printing, further expanding the materials options.

### Methods—Chemicals

Polyvinylpyrrolidone (PVP, M_{w},=40000 g/mol, e.g., Millipore-Sigma), polyvinyl alcohol (PVA, M_{w},=146,000-186,000, e.g., Sigma Aldrich), silver nitrate (AgNO₃, e.g., Fisher), sodium citrate (Na₃C₆H₅O₇, e.g., Sigma Aldrich), zinc oxide nanowires (ZnO NWs, NWZO01A5, ACS Materials), methanol (e.g., Fisher), zinc nitrate hexahydrate (Zn(NO₃)₂·6H₂O, Aldrich), 2-methylimidazole (e.g., MeIM, Fisher), polyimide films (e.g., DuPont), lignin (e.g., Kraft, Domtar), methyl ethyl ketone (e.g., MEK, Sigma Aldrich), and silver paste (e.g., Ted Palla) were used as received without further purification. Four types of filaments including polycarbonate (PC, Polymaker), thermoplastic polyurethane (TPU, 95 A, Overture), and polyvinylidene fluoride (PVDF, e.g., Fluorx), and polyethylene terephthalate glycol (PETG, e.g., Overture) were used for FFF. Deionized water (DI H₂O) was used to prepare the precursors solutions.

Preparation of lignin solution and lignin/silver mixture solution Kraft lignin was first dissolved in MEK (95 wt %) with a mass ratio of 1:3. Subsequently, 4.0 g of the mixture of Kraft lignin and MEK was dissolved in 10 g of a 2 wt % sodium hydroxide (NaOH) solution. PVA solution was prepared by fully dissolving PVA at 9 wt % in DI water at 90° C. for 1 h. Then, the obtained lignin solution was mixed with the PVA solution in a 1:1 volumetric ratio, and stirred until a dark brown homogeneous mixture was produced. To make the mixture of lignin and silver solution, silver ink precursor was added to the lignin/PVA solution at a volumetric ratio of 3:1. Subsequently, the mixture was thoroughly stirred for 1 h.

### Preparation of Silver Ink Solution

For embodiments including silver ink, first a Solution A was prepared by dissolving 0.30 g of sodium citrate and 0.025 g of PVP in 10 mL of DI H₂O. Then, a Solution B was prepared by dissolving 0.52 g of AgNO₃ in 8 mL of DI H₂O. Solution B was introduced dropwise into Solution A under continuous stirring for 1 h to obtain a silver ink solution.

### Materials Characterization

X-ray diffraction was obtained on Rigaku SmartLab with Cu Kα radiation (λ=0.15406 nm). Raman spectra were collected on a Renishaw Via Raman spectroscopy. The SEM images and element analysis by EDS were taken on an FEI Quanta 400 ESEM FEG system at a voltage of 20 kV.

### Design and Construction of the FMAP Platform

Certain embodiments of the FMAP platform were built based on a customized FFF 3D printer (e.g., Creality CR-10 V2). The original linear motion mechanism was kept without change. A customized rotational mechanism enabled by two orthogonal NEMA17 stepper motors with harmonic reducers, actuated by DRV8825 at 1/32 micro-stepping, was added. A LASERTREE 5 W laser module, an FFF end, and a DIW syringe were connected to the C-axis actuator. The control system was modified with Arduino Mega 2560 R3 and a Ramps 1.6+board. The firmware was modified based on an open-source GRBL-MEGA-5X system.

### Testing of a Capacitive-Sensing Slider

In certain aspects of the slider embodiment, the slider's functionality is calibrated by moving a finger along its surface, spanning from the leftmost end to the rightmost end. To establish a baseline, the minimum and maximum data points were obtained from both electrodes for normalization. Then, the normalized data collected from one electrode was subtracted from the normalized data collected from the other electrode. This subtraction yields linear relationship between the processed capacitance data and the output voltage, that which in turn controls the brightness of the LED. Wireless communication was made through a pair of Bluetooth devices. Repeated measurements were taken from the same samples for standard deviation calculation.

### Fabrication and Testing of a UV Sensor

To fabricate a UV sensor as described herein, a stencil outlining an Ag circuit was made by FFF of PETG. The silver ink was then deposited onto the stencil by DIW. Subsequently, the silver ink underwent FLI at a scan rate of 500 mm/min and a laser power of 3.5 W to obtain the Ag circuit. After that, electrical components including, a NE555 timer IC, a 10MΩ resistor, a 2.2 nf capacitor and a SMD LED were manually assembled into the circuit. Subsequently, 30 μL aqueous solution containing 3 mg/mL ZnO NPs—which serve as the UV sensitive material—was uniformly applied onto the Ag current collector on the top surface the whole packaged device by DIW.

To evaluate the UV sensing capabilities, a light source such as the AI-2UV20DC UV light source was employed. Adjusting the UV light intensity was accomplished through a shelf that could be raised or lowered, and a UV Meter (e.g., General Tools, UV513AB, 280-400 nm) was place together with the UV sensor for UV intensity measurement. Initially, the UV sensor was positioned immediately beneath the UV light source, and the shelf was adjusted to achieve a UV intensity of 1075 μW·cm⁻². The sensor's resistance response was recorded using a source meter (e.g., 2604B, Keithley Instruments). Subsequently, the shelf was progressively raised to lower the UV light intensity, eventually reaching 130 μW·cm⁻². Measurements were taken at each UV intensity level upon stabilization. The performance of the ZnO-based UV sensor was assessed based on its alterations in resistance.

### Fabrication and Testing of the Micro Electromagnet

For certain electromagnet embodiments, a stencil for later depositing the Ag and Fe was printed from PETG by FFF. The Ag and Fe inks were deposited onto the stencil by DIW, and were then induced to Ag and Fe via FLI a scan rate of 500 mm/min and a laser power of 3.5 W. A Hall sensor such as a 49E linear Hall sensor was used for magnetic field detection. Repeated measurements were taken from the same samples for standard deviation calculation.

### Testing of LIG Embedded Spring

For certain spring embodiments, a customized displacement controller was used to apply various displacements to the spring. The resistance response was measured by a source meter (2604B, Keithley Instruments). Repeated measurements were taken from the same samples for standard deviation calculation.

For synthesis of ZIF-8 via in-situ heating of microfluidic channel, current was applied to the LIG electrode by a connected DC power supply (Dr. Meter, HY3005F-3) for Joule heating. The temperature was periodically record by a FLIR E4 camera. After reaching a stable temperature, two precursors of 0.1 M Zn (NO₃)₂ and 0.8 M MeIM were fed into two inlets of the microfluidic reactor. The obtained products were collected from the outlet. The UV-vis adsorption spectra of the collected samples were measured by a PerkinElmer Lambda 35 UV-vis spectrometer.

### FEA Simulation of LIG-Embedded Spring

Compression tests of the spring embedded in LIG was conducted using commercial software such as COMSOL Multiphysics. The spring's shell material was defined as Polycarbonate [Solid], sourced from the COMSOL Material Library. A stationary analysis within a “Solid Mechanics” module was executed to determine the Mises stress distribution. This analysis was performed under prescribed displacement at the top surface, with the bottom surface fixed and all other surfaces left free.

### FEA Simulation of Microfluidic Channel Heating

The heating of a microfluidic channel with water flow was simulated using the COMSOL Multiphysics software. A stationary analysis, combining “Heat Transfer in Solids and Fluids” and “Laminar Flow”, was conducted to compute the temperature distribution. This simulation focused on a heat source positioned within the LIG region, applying a heat rate of 3 W. The microfluidic channel material was specified as Polycarbonate [Solid], while the fluid used within the channel was chosen as Water, a predefined liquid from the COMSOL Material Library. The physical model for water assumed it to be an incompressible Newtonian fluid, and turbulence effects were omitted. The inflow rate ranged from 4.5 μL/s to 18 μL/s, maintaining a constant temperature of 20° C. At the outlet, a pressure condition of 1 atm and a thermal insulation condition were applied as boundary conditions. Other surfaces were assigned convective heat flux and surface-to-ambient radiation conditions. These conditions were defined with an external temperature of 20° C., a heat transfer coefficient of 10 W/(m²K), and a surface emissivity of 1. To study the evolution of the temperature field within the channel over time, a time-dependent analysis was carried out with the same boundary conditions as the stationary analysis. The time-dependent simulation began at t=0 s, ended at t=300 s, and used a time step of 1 s.

### Design and Construction of FMAP Processing Apparatus

One embodiment of platform 100 was built upon a Creality CR-10 V2 3D printer, with the X and Y motion mechanisms upgraded to linear rails driven by a belt. The Z axis is driven by two stepper motors. A customized rotational mechanism, including two orthogonal NEMA17 stepper motors with harmonic reducers from robotdigg, was integrated. Motion control was achieved using components such as an Arduino Mega 2560 and a Ramps 1.6+board. Temperature control of the FFF hotend and build plate was managed by a separate control board such as a Creality V2.2 control board. This is one example of a configuration of platform 100 and/or components of platform 100 and is not limiting.

For all of the above-described embodiments and usages, any code and/or data or other information may be stored in a memory of the above-described system, and/or in a remote (e.g., cloud) storage system (e.g., in a dedicated database or other centralized storage mechanism). Embodiments of the invention may be described in the general context of computer-executable instructions, such as program modules, executed by one or more computers or other devices. The computer-executable instructions may be organized into one or more computer-executable components or modules. Generally, program modules include, but are not limited to, routines, programs, objects, components, and data structures that perform particular tasks or implement particular abstract data types. Aspects of the invention may be implemented with any number and organization of such components or modules. For example, aspects of the invention are not limited to the specific computer-executable instructions or the specific components or modules illustrated in the figures and described herein. Other embodiments of the invention may include different computer-executable instructions or components having more or less functionality than illustrated and described herein. Aspects of the invention may also be practiced in distributed computing environments where tasks are performed by remote processing devices that are linked through a communications network. In a distributed computing environment, program modules may be located in both local and remote computer storage media including memory storage devices.

In operation, a computer executes computer-executable code/instructions embodied in one or more computer-executable components stored on one or more computer-readable media to implement aspects of the invention described and/or illustrated herein. Code can include application source code, application object code, configuration data, additional input events, application states, assertion statements, validation results, and/or any other type of data. The order of execution or performance of the operations in embodiments of the invention illustrated and described herein is not essential, unless otherwise specified. That is, the operations may be performed in any order, unless otherwise specified, and embodiments of the invention may include additional or fewer operations than those disclosed herein. For example, it is contemplated that executing or performing a particular operation before, contemporaneously with, or after another operation is within the scope of aspects of the invention.

The raw and/or processed data and/or any related graphical or other representations of the data may be processed by the above-described computer system or the like and output for display on a display device such as a TV, monitor, mobile device (e.g., mobile phone or tablet) and the like such that a technician/practitioner/evaluator/therapist/user can view and/or manipulate the data (e.g., the data may be presented in a visual format for presenting certain aspects of the test results, for example as shown in the applicable above-noted figures). For example, a display monitor may be connected (e.g., wired or wirelessly) to the above-described computer system to provide a visual output on the computer system. The computer system may have an operating system with a graphical user interface capable of being used by a user to (i) input, view, execute and/or manipulate the above-described computer code and/or (ii) process the obtained sensor data and any related graphical representations of such data in the manners described above. The operating system may be capable of running software applications such as those described above for carrying out the above-described techniques and also any necessary post-processing and/or outputting of the obtained sensor data for viewing, such as for viewing by a therapist that is treating/diagnosing a patient/test subject. Additional software for other code/data manipulations and/or for generating other visuals relating to the data may also be present on the computer system.

In the present disclosure, all or part of the units or devices of any system and/or apparatus, and/or all or part of functional blocks in any block diagrams and flow charts may be executed by one or more electronic circuitries including a semiconductor device, a semiconductor integrated circuit (IC) (e.g., such as a processor), or a large-scale integration (LSI). The LSI or IC may be integrated into one chip and may be constituted through combination of two or more chips. For example, “processor” as used herein refers generally to any programmable system including systems and microcontrollers, reduced instruction set circuits (RISC), application specific integrated circuits (ASIC), programmable logic circuits (PLC), FPGA, and any other circuit or processor capable of executing the functions described herein. The functional blocks other than a storage element may be integrated into one chip. The integrated circuitry that is called LSI or IC in the present disclosure is also called differently depending on the degree of integrations, and may be called a system LSI, VLSI (very large-scale integration), or ULSI (ultra large-scale integration). For an identical purpose, it is possible to use an FPGA (field programmable gate array) that is programmed after manufacture of the LSI, or a reconfigurable logic device that allows for reconfiguration of connections inside the LSI or setup of circuitry blocks inside the LSI. Furthermore, part or all of the functions or operations of units, devices or parts or all of devices can be executed by software processing (e.g., coding, algorithms, etc.). In this case, the software is recorded one or more non-transitory computer-readable recording media, such as one or more ROMs, RAMs (e.g., DRAM, SRAM), optical disks, hard disk drives, solid-state memory, servers, cloud storage, and so on and so forth, having stored thereon executable instructions which can be executed to carry out the desired processing functions and/or circuit operations. For example, when the software is executed by a processor, the software causes the processor and/or a peripheral device to execute a specific function within the software. The system/method/device of the present disclosure may include (i) one or more non-transitory computer-readable recording mediums that store the software, (ii) one or more processors (e.g., for executing the software or for providing other functionality), and (iii) a necessary hardware device (e.g., a hardware interface). Artificial intelligence in any and all types and formats may be utilized in any of the steps, techniques, protocols, analyses, and/or any other manipulation, generation, or other creation of data, results and/or any information described herein. This includes but is not limited to computer visions, machine learning, deep learning, neural networks, algorithms, and any data, models, and training needed for such. The above examples are examples only, and thus are not intended to limit in any way the definitions and/or meanings of the terms. Computation may be accomplished by local computing devices as described herein, and/or cloud computing via an internet connection, and/or combinations of local and/or cloud computing devices.

Data conduits and any other communication or data transfer as described herein may include wired or wireless connections. For example, a wired network connection (e.g., Ethernet or an optical fiber), a wireless communication means, such as radio frequency (RF), e.g., FM radio and/or digital audio broadcasting, WiFi (e.g., IEEE 802.11 standards), WIMAX, a short-range wireless communication channel such as BLUETOOTH, a cellular phone technology (e.g., GSM), a satellite communication link, and/or any other suitable communication means. Such data conduits, in particular wired versions, can also be referred to as a system bus.

The embodiments were chosen and described in order to best explain the principles of the disclosure and its practical application to thereby enable others skilled in the art to best utilize the disclosure in various embodiments and with various modifications as are suited to the particular use contemplated. Aspects of the disclosed embodiments may be mixed to arrive at further embodiments within the scope of the invention.

As various modifications could be made in the constructions and methods herein described and illustrated without departing from the scope of the disclosure, it is intended that all matter contained in the foregoing description or shown in the accompanying drawings shall be interpreted as illustrative rather than limiting. Thus, the breadth and scope of the present disclosure should not be limited by any of the above-described example embodiments, but should be defined only in accordance with the following claims appended hereto and their equivalents.

Various aspects of the embodiments described above may be used alone, in combination, or in a variety of arrangements not specifically discussed in the embodiments described in the foregoing and is therefore not limited in its application to the details and arrangement of components set forth in the foregoing description or illustrated in the drawings. For example, aspects described in one embodiment may be combined in any manner with aspects describe in other embodiments.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

Also, the phraseology and terminology used herein is for the purpose of description and should not be regarded as limiting. The use of “including,” “comprising,” “having,” “containing,” “involving,” and variations thereof herein, is meant to encompass the items listed thereafter and equivalents thereof as well as additional items.

The word “example” is used herein to mean serving as an example, instance, or illustration. Any embodiment, implementation, process, feature, etc. described herein as example should therefore be understood to be an illustrative example and should not be understood to be a preferred or advantageous example unless otherwise indicated.

It should be noted that, as used herein, the term “couple” is not limited to a direct mechanical, electrical, and/or communication connection between components, but may also include an indirect mechanical, electrical, and/or communication connection between multiple components.

Having thus described several aspects of at least one embodiment, it is to be appreciated that various alternations, modifications, and improvements will readily occur to those skilled in the art. Such alterations, modifications, and improvements are intended to be part of this disclosure and are intended to be within the spirit and scope of the principles described herein. Accordingly, the foregoing description and drawings are by way of example only.

What is claimed is:

1. A fabrication system for programmed multimaterial assembly via a freeform multimaterial assembly process, the fabrication system comprising:
a multi-axis actuation system; and
a computing device comprising at least one processor and at least one memory in communication with the at least one processor, the computing device being in operative communication with the multi-axis actuation system, the at least one memory storing instructions that, when executed, cause the at least one processor to:
control the multi-axis actuation system to synergistically integrate a fused filament fabrication (FFF) process and a direct ink writing (DIW) process with a freeform laser induction (FLI) process for the construction of 3D engineered structures;
cause generation, via the controlled multi-axis actuation system, of structural components of one or more target 3D engineered structures via the FFF process and the DIW process;
cause generation, via the controlled multi-axis actuation system and based on the generated structural components, of functional materials via the FLI process; and
cause construction, via the controlled multi-axis actuation system, and based on the generated structural components and the generated functional materials, of the one or more target 3D engineered structures.

2. The fabrication system according to claim 1, wherein the multi-axis actuation system is a 5-axis actuation system.

3. The fabrication system according to claim 2, wherein the 5-axis actuation system includes three linear axes and two rotational axes.

4. The fabrication system according to claim 1, wherein the instructions, when executed, further cause the at least one processor to:
execute a modular control scheme enabling coordinated toolpath generation for the FFF process, the DIW process, and the FLI process within a single instruction set.

5. The fabrication system according to claim 1, wherein the multi-axis actuation system includes a plurality of end effectors.

6. The fabrication system according to claim 5, wherein the plurality of end effectors includes an FFF end used in conjunction with the FFF process, a DIW nozzle used in conjunction with the DIW process, and a laser module used in conjunction with the FLI process.

7. The fabrication system according to claim 6, wherein the instructions, when executed, further cause the at least one processor to:
cause the multi-axis actuation system to rotate one of the FFF end and the DIW nozzle by a designated angle as part of the generation of the structural components.

8. The fabrication system according to claim 6, wherein the instructions, when executed, further cause the at least one processor to:
cause control of a laser of the laser module to convert (i) materials of the structural components printed via the FFF process and (ii) ink deposited via the DIW process into the functional materials.

9. The fabrication system according to claim 1, further comprising one or more sensors configured to provide real-time feedback to the computing device for adjusting process parameters during fabrication of the one or more target 3D engineered structures.

10. The fabrication system according to claim 1, wherein the one or more target 3D engineered structures includes an electrical or electronic component.

11. A computer-implemented method for programmed multimaterial assembly via a freeform multimaterial assembly process, implemented via a multi-axis actuation system in operative communication with a computing device, the computing device comprising at least one processor and at least one memory in communication with the at least one processor, the computer-implemented method comprising:
controlling the multi-axis actuation system to synergistically integrate a fused filament fabrication (FFF) process and a direct ink writing (DIW) process with a freeform laser induction (FLI) process for the construction of 3D engineered structures;
causing generation, via the controlled multi-axis actuation system, of structural components of one or more target 3D engineered structures via the FFF process and the DIW process;
causing generation, via the controlled multi-axis actuation system and based on the generated structural components, of functional materials via the FLI process; and
causing construction, via the controlled multi-axis actuation system, and based on the generated structural components and the generated functional materials, of the one or more target 3D engineered structures.

12. The computer-implemented method according to claim 11, wherein the multi-axis actuation system is a 5-axis actuation system.

13. The computer-implemented method according to claim 12, wherein the 5-axis actuation system includes three linear axes and two rotational axes.

14. The computer-implemented method according to claim 11, further comprising executing, via the computing device, a modular control scheme enabling coordinated toolpath generation for the FFF process, the DIW process, and the FLI process within a single instruction set.

15. The computer-implemented method according to claim 11, wherein the multi-axis actuation system includes a plurality of end effectors.

16. The computer-implemented method according to claim 15, wherein the plurality of end effectors includes an FFF end used in conjunction with the FFF process, a DIW nozzle used in conjunction with the DIW process, and a laser module used in conjunction with the FLI process.

17. The computer-implemented method according to claim 16, further comprising:
causing the multi-axis actuation system to rotate one of the FFF end and the DIW nozzle by a designated angle as part of the generation of the structural components.

18. The computer-implemented method according to claim 16, further comprising:
causing control of a laser of the laser module to convert (i) materials of the structural components printed via the FFF process and (ii) ink deposited via the DIW process into the functional materials.

19. The computer-implemented method according to claim 11, wherein one or more sensors are in operative communication with the computing device, and the computer-implemented method further comprises:
providing, via the one or more sensors, real-time feedback to the computing device for adjusting process parameters during fabrication of the one or more target 3D engineered structures.

20. The computer-implemented method according to claim 11, wherein the one or more target 3D engineered structures includes an electrical or electronic component.
